(19) United States
(12) Patent Application Publication
(10) Pub. No.: US 2026/0239599 A1
(43) Pub. Date: Aug. 13, 2026

(54) SEMICONDUCTOR DEVICE AND METHOD FOR FABRICATING THE SAME

(71) Applicant: SK hynix Inc., Gyeonggi-do (KR)

(72) Inventors: Dong Il SONG, Gyeonggi-do (KR); Jeong Hoon KWON, Gyeonggi-do (KR)

(21) Appl. No.: 19/248,482

(22) Filed: Jun. 25, 2025

(30) Foreign Application Priority Data
Feb. 12, 2025 (KR) 10-2025-0017717

(51) Int. Cl. H10B 12/00

(52) U.S. Cl. CPC H10B 12/30; H10B 12/03; H10B 12/05

(57) ABSTRACT

A semiconductor device including high-integrated memory cells and a method for fabricating the semiconductor device is provided. The semiconductor device includes vertical and horizontal arrangements of nano sheets that are horizontally oriented, a vertical arrangement of first conductive lines that surround portions of the nano sheets in the horizontal arrangement; a supporter structure adjacent to the vertical and horizontal arrangements of the nano sheets; second conductive lines embedded in the supporter structure and coupled in common to first edges of the nano sheets in the vertical arrangement; and a dummy structure including a bottom isolation portion in contact with bottom portions of the second conductive lines.

### CROSS-REFERENCE TO RELATED APPLICATIONS

The present application claims priority under 35 U.S.C 119(a) to Korean Patent Application No. 10-2025-0017717, filed on Feb. 12, 2025, which is incorporated herein by reference in its entirety.

### BACKGROUND

### 1. Field

Various embodiments of the present disclosure relate generally to a semiconductor device, and more particularly, to a semiconductor device including three-dimensional (3D) memory cells, and a method for fabricating the semiconductor device.

### 2. Description of the Related Art

Recently, in order to cope with the large capacity and miniaturization of a memory device, a three-dimensional (3D) memory device in which a plurality of memory cells are stacked has been proposed

### SUMMARY

Embodiments of the present disclosure are directed to a semiconductor device including high-integrated memory cells, and a method for fabricating the semiconductor device.

In accordance with an embodiment of the present disclosure, a semiconductor device may include vertical and horizontal arrangements of nano sheets that are horizontally oriented; a vertical arrangement of first conductive lines that surround portions of the nano sheets in the horizontal arrangement; a supporter structure adjacent to the vertical and horizontal arrangements of the nano sheets; second conductive lines embedded in the supporter structure and coupled in common to first edges of the nano sheets in the vertical arrangement; and a dummy structure including a bottom isolation portion in contact with bottom portions of the second conductive lines.

In accordance with an embodiment of the present disclosure, a method for fabricating a semiconductor device may include forming a dummy mold over a substrate; forming a mold stack including mold layers that are vertically stacked over the dummy mold; forming a vertical arrangement of narrow sheets by trimming first portions of the mold layers; forming a dummy recess by trimming a first portion of the dummy mold; forming first conductive lines that surround the narrow sheets in the vertical arrangement and are horizontally oriented; forming sacrificial growth layers on one side of the narrow sheets in the vertical arrangement; forming a bottom isolation portion that fills the dummy recess; forming a supporter structure that vertically extends from the bottom isolation portion and supports the sacrificial growth layers; forming a plurality of support openings that are vertically oriented in the supporter structure by removing the sacrificial growth layers; and forming a plurality of second conductive lines embedded in the support openings.

Wherein forming the sacrificial growth layers includes growing an epitaxial layer through selective epitaxial growth.

Wherein the sacrificial growth layers include an epitaxial layer of silicon germanium layers.

Wherein the bottom isolation portion and the supporter structure are formed of an integral structure.

wherein the supporter structure includes support bodies that are vertically oriented from the bottom isolation portion; inner spacers configured to couple the support bodies to each other and adjacent to the narrow sheets; and outer spacers disposed on outer sides of the sacrificial growth layers.

Wherein the bottom isolation portion and the supporter structure each include a low-k material, silicon oxide, silicon carbon oxide, silicon nitride, an air gap, or a combination thereof.

A method for fabricating a semiconductor device may further include forming first contact nodes on one side of the narrow sheets exposed by the plurality of support openings, before forming the plurality of second conductive lines.

A method for fabricating a semiconductor device may further include, after forming the plurality of the second conductive lines, forming a vertical arrangement of wide sheets by trimming second portions of the mold layers; forming second contact nodes on the wide sheets; and forming data storage elements on the second contact nodes.

These and other features and advantages of the embodiments of the present disclosure will become apparent to those skilled in the art from the following detailed description in conjunction with the following drawings.

### BRIEF DESCRIPTION OF THE DRAWINGS

FIG. 1A is a schematic perspective view illustrating a memory cell in accordance with an embodiment of the present disclosure.

FIG. 1B is a schematic side cross-sectional view of the memory cell illustrated in FIG. 1A.

FIG. 2A is a schematic perspective view illustrating a semiconductor device in accordance with an embodiment of the present disclosure.

FIG. 2B is a partial perspective view of the semiconductor device to describe a method of forming a tier illustrated in FIG. 2A.

FIG. 2C is a partial perspective view of the semiconductor device to describe a first conductive line illustrated in FIG. 2A.

FIG. 2D is a partial perspective view of the semiconductor device to describe a first spacer illustrated in FIG. 2A.

FIG. 2E is a partial perspective view of the semiconductor device to describe a second spacer illustrated in FIG. 2A.

FIG. 3A is a perspective view illustrating a supporter structure illustrated in FIG. 2A.

FIG. 3B is a cross-sectional view of an array of second conductive lines.

FIG. 3C is a perspective view illustrating a second conductive line.

FIG. 4A is a schematic plan view of a semiconductor device in accordance with an embodiment of the present disclosure.

FIG. 4B is a schematic cross-sectional view of the semiconductor device taken along line A-A′ illustrated in FIG. 4A.

FIG. 4C is a schematic cross-sectional view of the semiconductor device taken along line B-B′ illustrated in FIG. 4A.

FIG. 4D is a schematic cross-sectional view of the semiconductor device taken along line C-C′ illustrated in FIG. 4A.

FIG. 4E is a schematic cross-sectional view of the semiconductor device taken along line D-D′ illustrated in FIG. 4A.

FIGS. 5A to 25B illustrate various views of a semiconductor device formed utilizing a method for fabricating the semiconductor device in accordance with an embodiment of the present disclosure.

FIGS. 26A and 26B are schematic cross-sectional views of a semiconductor device in accordance with embodiments of the present disclosure.

FIGS. 27A and 27B illustrate various views illustrating a stack assembly in accordance with embodiments of the present disclosure.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of this disclosure.

The following embodiment relates to three-dimensional memory cells, in which memory cells are vertically stacked to increase memory cell density and reduce parasitic capacitance.

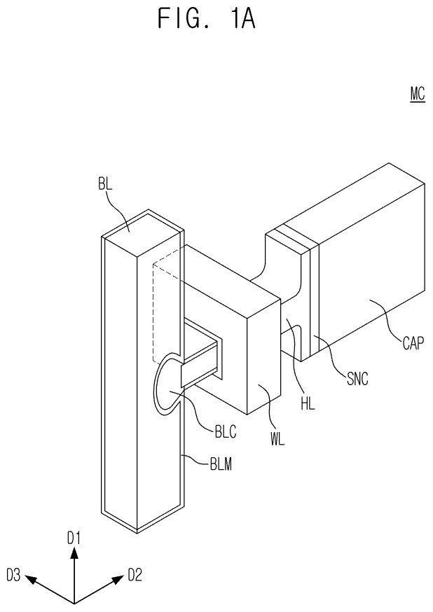

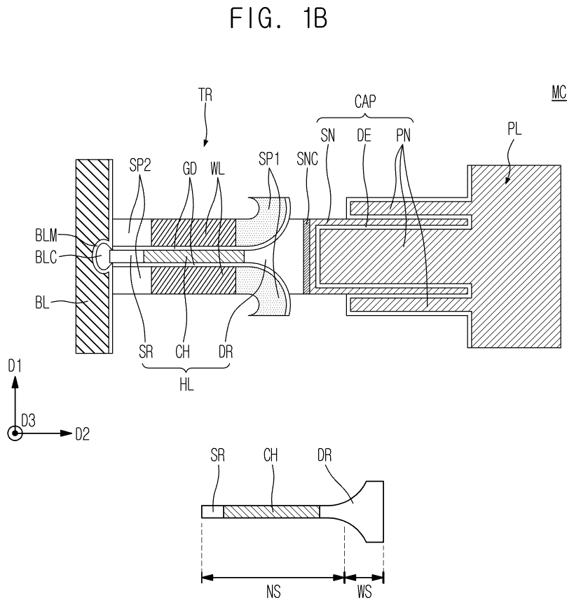

FIG. 1A is a schematic perspective view illustrating a memory cell MC in accordance with an embodiment of the present disclosure. FIG. 1B is a schematic side cross-sectional view of the memory cell MC illustrated in FIG. 1A.

Referring to FIGS. 1A and 1B, the memory cell MC may include a switching element TR and a data storage element CAP operatively coupled to each other.

The switching element TR has a function of controlling voltage or current supply to the data storage element CAP during a data write operation and/or a data read operation performed on the data storage element CAP. The switching element TR may include a nano sheet HL, a nano sheet dielectric layer GD, and a first conductive line WL. The first conductive line WL may include a horizontal conductive line or a horizontal word line, and the nano sheet HL may include an active layer. The switching element TR may include a transistor, and in this case, the first conductive line WL may serve as a gate electrode. The switching element TR may also be referred to as a “nano sheet transistor”, a “cell transistor”, an “access element” or a “selection element”. The first conductive line WL may be referred to as a “horizontal gate electrode” or a “horizontal word line”.

The nano sheet HL may extend in a second direction D2 that intersects with the first direction D1. The first conductive line WL may extend in a third direction D3 that intersects with the first direction D1 and the second direction D2. The first direction D1 may be a vertical direction, the second direction D2 may be a first horizontal direction, and the third direction D3 may be a second horizontal direction. The nano sheet HL may extend in the first horizontal direction, i.e., the second direction D2, and the first conductive line WL may extend in the second horizontal direction, i.e., the third direction D3. The nano sheet HL may be referred to as a “horizontal layer”.

The nano sheet HL may include a first doped region SR, a second doped region DR, and a channel CH between the first doped region SR and the second doped region DR. The first doped region SR may be coupled to a second conductive line BL, and the second doped region DR may be coupled to the data storage element CAP. The nano sheet HL may be horizontally oriented in the second direction D2 from the second conductive line BL. The first doped region SR, the channel CH and the second doped region DR may be horizontally formed in the second direction D2. A height of the second doped region DR in the first direction D1 may be greater than a height of the channel CH in the first direction D1. A length of the second doped region DR in the second direction D2 may be less than a length of the channel CH in the second direction D2. Lengths of the first doped region SR, the channel CH and the second doped region DR in the third direction D3 may be equal to one another.

The nano sheet HL may include a first sheet region NS and a second sheet region WS that are horizontally disposed in the second direction D2. The second sheet region WS may extend from the first sheet region NS. The second sheet region WS may have a thickness that gradually increases in the second direction D2 from the first sheet region NS toward the data storage element CAP between the first sheet region NS and the data storage element CAP. An average vertical height or thickness of the second sheet region WS in the first direction D1 may be greater than an average vertical height or thickness of the first sheet region NS. Hereinafter, the first sheet region NS is referred to as a “narrow sheet”, and the second sheet region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS, and the second doped region DR may be disposed in the wide sheet WS. The channel CH formed in the narrow sheet NS may be referred to as a “narrow channel” or a “flat channel”. A portion of the second doped region DR may extend to be disposed in the narrow sheet NS. The second doped region DR may include a thick portion disposed in the wide sheet WS and a thin portion disposed in the narrow sheet NS. One side of the wide sheet WS and one side of the second doped region DR, which contact the data storage element CAP, may each have a flat side shape.

A horizontal length of the wide sheet WS in the second direction D2 may be less than a horizontal length of the narrow sheet NS. The narrow sheet NS may be referred to as a “long sheet”, and the wide sheet WS may be referred to as a “short sheet”.

The nano sheet HL may include a semiconductive material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), indium tin zinc oxide (InSnZnO), zinc tin oxide (ZnSnO), or a combination thereof. In some embodiments, the nano sheet HL may include conductive metal oxide. In some embodiments, the nano sheet HL may include a two-dimensional material, for example, molybdenum disulfide (MoS₂), tungsten disulfide (WS₂), or molybdenum selenide (MoSe₂).

When the nano sheet HL is formed of the oxide semiconductor material, the channel CH may also be formed of the oxide semiconductor material, and the first and second doped regions SR and DR may be omitted. The nano sheet HL may also be referred to as an “active layer” or a “thin body”.

The first doped region SR and the second doped region DR may be doped with the same conductivity type of an impurity. Each of the first doped region SR and the second doped region DR may be doped with an N-type conductive impurity or a P-type conductive impurity. Each of the first doped region SR and the second doped region DR may include at least one impurity selected from among arsenic (As), phosphorus (P), boron (B), indium (In), and combinations thereof. The first doped region SR may be coupled to the second conductive line BL, and the second doped region DR may be coupled to the data storage element CAP. The first and second doped regions SR and DR may be referred to as “first and second source/drain regions”.

The first conductive line WL may have a gate-all-around (GAA) structure. For example, the first conductive line WL may surround the nano sheet HL and extend in the third direction D3. The nano sheet dielectric layer GD may be formed between the nano sheet HL and the first conductive line WL. The nano sheet dielectric layer GD may surround the nano sheet HL. The first conductive line WL may surround the nano sheet HL on the nano sheet dielectric layer GD.

The first conductive line WL may include a metal-based material, a semiconductive material, or a combination thereof. The first conductive line WL may include molybdenum, molybdenum nitride, ruthenium, titanium nitride, tungsten, polysilicon, or a combination thereof. For example, the first conductive line WL may include a TiN/W stack in which titanium nitride and tungsten are sequentially stacked. The first conductive line WL may include an N-type work function material or a P-type work function material. The N-type work function material may have a low work function of approximately 4.5 eV or less, and the P-type work function material may have a high work function of approximately 4.5 eV or greater. The first conductive line WL may include a stack of a low work function material and a high work function material.

The nano sheet dielectric layer GD may be disposed between the nano sheet HL and the first conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxynitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by thermal oxidation of a semiconductive material. In some embodiments, forming the nano sheet dielectric layer GD may include depositing a nano sheet dielectric material on a semiconductive material and oxidizing the semiconductive material.

The second conductive line BL may be vertically oriented in the first direction D1. The second conductive line BL may include a bit line. The second conductive line BL may be referred to as a “vertical conductive line”, a “vertically-oriented bit line”, a “vertically-extending bit line”, or a “pillar-shaped bit line”. The second conductive line BL may include a conductive material. The second conductive line BL may include a silicon-based material, a metal-based material, or a combination thereof. The second conductive line BL may include polysilicon, metal, metal nitride, metal silicide, or a combination thereof. The second conductive line BL may include polysilicon, titanium nitride, tungsten, or a combination thereof. For example, the second conductive line BL may include a titanium nitride/tungsten (TiN/W) stack in which titanium nitride and tungsten are sequentially stacked.

The data storage element CAP may include a memory element such as a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend in the second direction D2 from the nano sheet HL. The first electrode SN, the dielectric layer DE and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region DR of the nano sheet HL. The second electrode PN of the data storage element CAP may be coupled to a common plate PL.

The data storage element CAP may have a three-dimensional structure. The first electrode SN may have a three-dimensional structure, which may have a horizontal three-dimensional structure that is oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces and cylindrical outer surfaces of the first electrode SN.

In some embodiments, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may each include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode PN may also include a combination of a metal-based material and a silicon-based material.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), strontium titanium oxide (SrTiO₃), or a combination thereof. In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer”. In some embodiments, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Because the dielectric layer DE includes a high band gap material, leakage current may be suppressed. The high band gap material may be thinner than the high-k material. In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, an HAHA (HfO₂/Al₂O₃/HfO₂/Al₂O₃) stack, an HAHAH (HfO₂/Al₂O₃/HfO₂/Al₂O₃/HfO₂) stack, an HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, an HZHZ (HfO₂/ZrO₂/HfO₂/ZrO₂) stack, an AHZAZHA (Al₂O₃/HfO₂/ZrO₂/Al₂O₃/ZrO₂/HfO₂/Al₂O₃) stack, or a ZHZAZHZAT (ZrO₂/HfO₂/ZrO₂/Al₂O₃/ZrO₂/HfO₂/ZrO₂/Al₂O₃/TiO₂) stack. In the above-described stack structures, aluminum oxide (Al₂O₃) may be thinner than zirconium oxide (ZrO₂) and hafnium oxide (HfO₂).

In some embodiments, the dielectric layer DE may include a high-k material and a high band gap material. The dielectric layer DE may have a laminated structure in which a plurality of high-k materials and a plurality of high band gap materials are stacked or an intermixed structure in which a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, the data storage element CAP may further include a plurality of interface control layers to alleviate leakage current. The interface control layers may each include titanium oxide (TiO₂), tantalum oxide (Ta₂O₅), niobium oxide (Nb₂O₅), niobium nitride (NbN), niobium oxynitride (NbON), or a combination thereof. The data storage element CAP may include a first interface control layer, a second interface control layer, or a combination thereof. The first interface control layer and the second interface control layer may be conductive or dielectric. The first interface control layer may be formed between the first electrode SN and the dielectric layer DE, and the second interface control layer may be formed between the dielectric layer DE and the second electrode PN. The first interface control layer and the second interface control layer may be the same material or different materials. For example, a structure of the data storage element CAP in which the first interface control layer, the dielectric layer DE and the second interface control layer are sequentially stacked may include an NZHZAZHZATN (Nb₂O₅/ZrO₂/HfO₂/ZrO₂/Al₂O₃/ZrO₂/HfO₂/ZrO₂/Al₂O₃/TiO₂/Nb₂O₅) stack.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the second conductive line BL and the nano sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the second doped region DR of the nano sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped silicon, and the second doped region DR may include an impurity diffused from the second contact node SNC. A height of the first contact node BLC in the first direction D1 may be less than a height of the second contact node SNC in the first direction D1. The height of the first contact node BLC in the first direction D1 may be greater than a height of the channel CH in the first direction D1.

The nano sheet HL may include a first edge and a second edge. The first edge may refer to a portion of the first doped region SR electrically coupled to the second conductive line BL, and the second edge may refer to a portion of the second doped region DR electrically coupled to the first electrode SN of the data storage element CAP.

The memory cell MC may further include a barrier layer BLM between the first contact node BLC and the second conductive line BL. The barrier layer BLM may include metal nitride such as titanium nitride. In some embodiments, the memory cell MC may further include an ohmic contact layer between the barrier layer BLM and the first contact node BLC. The ohmic contact layer may include metal silicide.

The memory cell MC may further include a first spacer SP1 and a second spacer SP2. The first spacer SP1 may be disposed between the first conductive line WL and the second doped region DR. The second spacer SP2 may be disposed between the first conductive line WL and the second conductive line BL. The first and second spacers SP1 and SP2 may each include a dielectric material. The first and second spacers SP1 and SP2 may each include silicon oxide, silicon nitride, or a combination thereof. The first spacer SP1 may surround the second doped region DR of the nano sheet HL, and the second spacer SP2 may surround the first doped region SR of the nano sheet HL. The first and second spacers SP1 and SP2 may be disposed on both sidewalls of the first conductive line WL. That is, the first and second spacers SP1 and SP2 may extend in the third direction D3.

In an embodiment, the first contact node BLC may be selectively grown from the narrow sheet NS of the nano sheet HL. The first contact node BLC may be formed by selective epitaxial growth (SEG). For example, the first contact node BLC may be a silicon epitaxial layer formed by the SEG. The first contact node BLC may be a doped silicon epitaxial layer. The second contact node SNC may be selectively grown from the wide sheet WS of the nano sheet HL. The second contact node SNC may be formed by the SEG. For example, the second contact node SNC may be a silicon epitaxial layer formed by the SEG. The second contact node SNC may be a doped silicon epitaxial layer.

The first contact node BLC may be a narrow sheet-side contact node, and the second contact node SNC may be a wide sheet-side contact node.

From another perspective, the memory cell MC may have a 1T-1C structure, where 1T may refer to one switching element TR, and 1C may refer to one data storage element CAP. When the memory cell MC is a DRAM cell having the 1T-1C structure, 1T may refer to one cell transistor, and 1C may refer to one capacitor. Accordingly, a gate of the cell transistor may be a word line, a first source/drain region of the cell transistor may be coupled to a bit line, and a second source/drain region of the cell transistor may be coupled to the capacitor. The bit line may correspond to the second conductive line BL of FIGS. 1A and 1B, the word line may correspond to the first conductive line WL of FIGS. 1A and 1B, and the capacitor may correspond to the data storage element CAP of FIGS. 1A and 1B. In addition, the first source/drain region may correspond to the first doped region SR of FIGS. 1A and 1B, and the second source/drain region may correspond to the second doped region DR of FIGS. 1A and 1B.

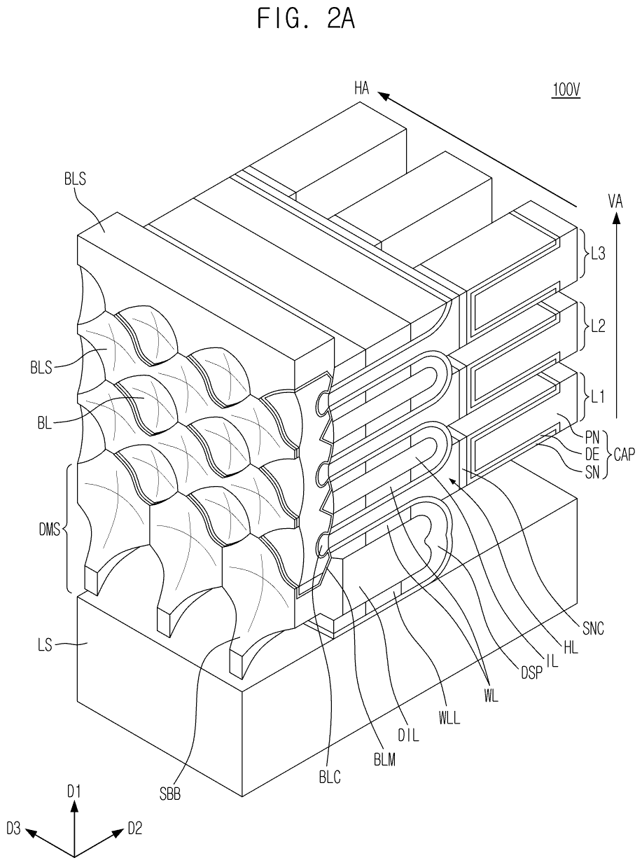

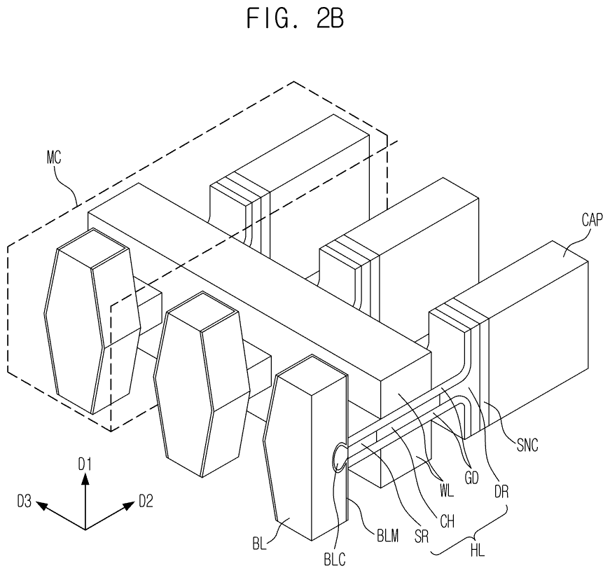

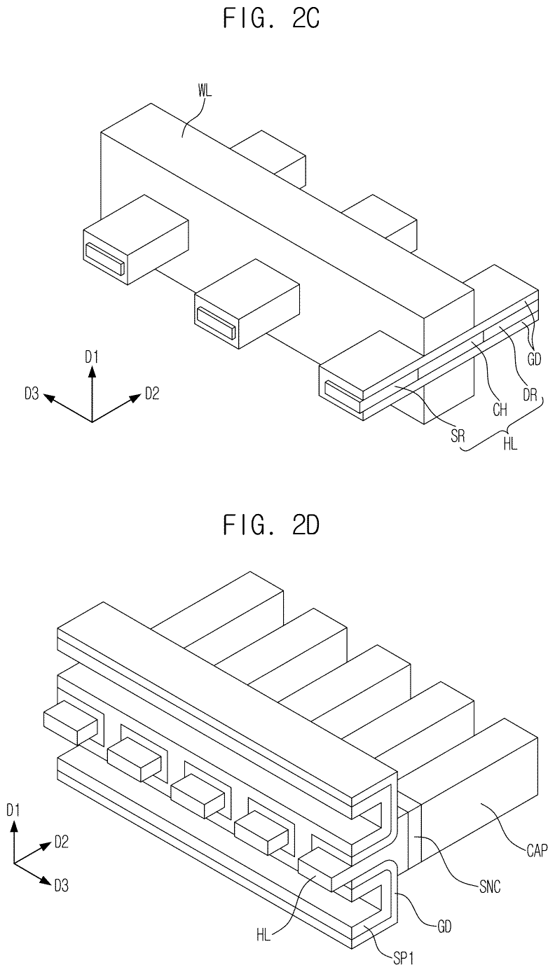

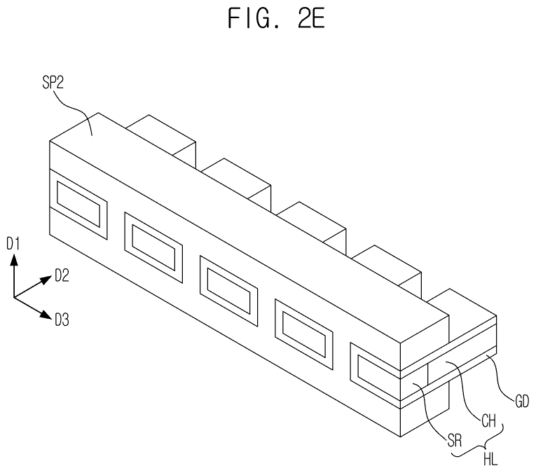

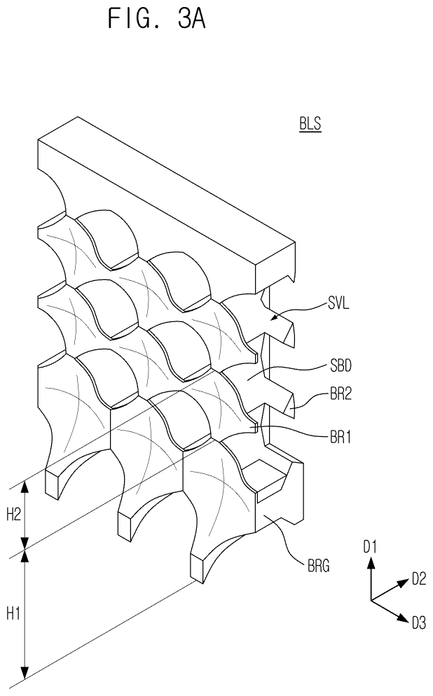

FIG. 2A is a schematic view illustrating a semiconductor device 100V in accordance with an embodiment of the present disclosure. FIG. 2B is a partial perspective view of the semiconductor device 100V to describe a method of forming a tier illustrated in FIG. 2A. FIG. 2C is a partial perspective view of the semiconductor device 100V to describe a first conductive line WL illustrated in FIG. 2A. FIG. 2D is a partial perspective view of the semiconductor device 100V to describe a first spacer SP1 illustrated in FIG. 2A. FIG. 2E is a partial perspective view of the semiconductor device 100V to describe a second spacer SP2 illustrated in FIG. 2A.

Referring to FIGS. 2A to 2E, the semiconductor device 100V may include a three-dimensional array disposed over a lower structure LS.

The lower structure LS may include a substrate. The lower structure LS may be a material appropriate for semiconductor processing. The lower structure LS may include a semiconductor substrate, a conductive material, a dielectric material, a semiconductive material, or a combination thereof. The lower structure LS may include silicon, monocrystalline silicon, polysilicon, amorphous silicon, silicon germanium, monocrystalline silicon germanium, polycrystalline silicon germanium, carbon-doped silicon, epitaxial silicon, a combination thereof, or multilayers thereof. The lower structure LS may also include another semiconductor material such as germanium. The lower structure LS may also include a III-V group semiconductor substrate, for example, a compound semiconductor substrate such as GaAs.

The semiconductor device 100V may include a three-dimensional array of memory cells MC. Detailed descriptions of the memory cells MC are provided above with reference to FIGS. 1A and 1B.

The semiconductor device 100V may include a horizontal arrangement HA and vertical arrangement VA of the memory cells MC. The memory cells MC in the horizontal arrangement HA may be horizontally spaced apart in a third direction D3. The memory cells MC in the vertical arrangement VA may be vertically stacked in a first direction D1. The memory cells MC in the horizontal arrangement HA may be vertically stacked in the first direction D1. The vertical arrangement VA of the memory cells MC may refer to a structure in which the horizontal arrangement HA of the memory cells MC are vertically stacked in the first direction D1. The semiconductor device 100V may include a horizontal arrangement of vertical conductive lines in which the vertical conductive lines are arranged in the third direction D3. The horizontal arrangement of the vertical conductive lines may include the horizontal arrangement HA of second conductive lines BL. The semiconductor device 100V may include a vertical arrangement of horizontal conductive lines in which the horizontal conductive lines are arranged in the first direction D1. The vertical arrangement of the horizontal conductive lines may include the vertical arrangement VA of first conductive lines WL.

The memory cells MC in the horizontal arrangement HA may be coupled to different second conductive lines BL and share one first conductive line WL. The memory cells MC in the vertical arrangement VA may share different first conductive lines WL and be coupled to one second conductive line BL. The vertical arrangement VA may include a plurality of tiers L1, L2 and L3. For example, the vertical arrangement VA of the semiconductor device 100V may include a first tier L1, a second tier L2, and a third tier L3, which are sequentially stacked. Each of inter-cell dielectric layers IL may be formed between the memory cells MC in the vertical arrangement VA.

Each of the memory cells MC may include a switching element TR and a data storage element CAP. The switching element TR may include a nano sheet HL, a nano sheet dielectric layer GD, and the first conductive line WL. The nano sheet HL may include a first doped region SR, a channel CH, and a second doped region DR. A first contact node BLC and a barrier layer BLM may be formed between the first doped region SR of the nano sheet HL and the second conductive line BL. A second contact node SNC may be formed between the second doped region DR of the nano sheet HL and the data storage element CAP. The nano sheet HL may be surrounded by the nano sheet dielectric layer GD. The first conductive line WL may extend in the third direction D3 while surrounding the channels CH of the nano sheets HL on the nano sheet dielectric layer GD.

The semiconductor device 100V may include the horizontal arrangement HA and vertical arrangement VA of the nano sheets HL. The semiconductor device 100V may include the horizontal arrangement HA and vertical arrangement VA of the switching elements TR. The semiconductor device 100V may include the horizontal arrangement HA of the second conductive lines BL. The semiconductor device 100V may include the vertical arrangement VA of the first conductive lines WL.

The semiconductor device 100V may further include first spacers SP1 and second spacers SP2. The first spacers SP1 and second spacers SP2 may each include a single spacer structure or a multi-spacer structure. The first spacers SP1 may surround first portions of the nano sheets HL in the horizontal arrangement HA. The first conductive lines WL may surround second portions of the nano sheets HL in the horizontal arrangement HA. The second spacers SP2 may surround third portions of the nano sheets HL in the horizontal arrangement HA. Specifically, the first spacers SP1 may extend in the third direction D3 while surrounding the nano sheets HL in the horizontal arrangement HA. The second spacers SP2 may extend in the third direction D3 while surrounding the nano sheets HL in the horizontal arrangement HA. More specifically, the first spacers SP1 may extend in the third direction D3 while surrounding the second doped regions DR in the horizontal arrangement HA. The second spacers SP2 may extend in the third direction D3 while surrounding the first doped regions SR in the horizontal arrangement HA. The first conductive lines WL may extend in the third direction D3 while surrounding the channels CH of the nano sheets HL in the horizontal arrangement HA. In this way, the first conductive lines WL, the first spacers SP1 and the second spacers SP2 may surround the nano sheets HL disposed at the same horizontal level. In some embodiments, the first spacers SP1 that are vertically arranged may be merged with each other.

The semiconductor device 100V may further include a supporter structure BLS. The supporter structure BLS is disposed over the lower structure LS. The semiconductor device further includes a bottom isolation portion SBB between the lower structure LS and the supporter structure BLS. The supporter structure BLS and the bottom isolation portion SBB may be configured to support the second conductive lines BL. The supporter structure BLS may be adjacent to the vertical arrangement VA and horizontal arrangement HA of the nano sheets HL. The supporter structure BLS and the bottom isolation portion SBB may have an integral structure (or continuous structure) or a frame structure. The supporter structure BLS and the bottom isolation portion SBB may include an integral structure of a dielectric material. The second conductive lines BL may be formed to be self-aligned with the supporter structure BLS, and the supporter structure BLS may be vertically oriented in an extension direction of the second conductive lines BL. The supporter structure BLS may include a low-k material, silicon oxide, silicon carbon oxide, silicon nitride, an air gap, or a combination thereof. The bottom isolation portion SBB may be simultaneously formed while the supporter structure BLS is formed, which is to be described later.

The semiconductor device 100V may further include a dummy structure DMS disposed below the supporter structure BLS. The dummy structure DMS may include dummy dielectric layers DIL, dummy spacers DSP, and dummy conductive lines WLL. The dummy structure DMS may include the bottom isolation portion SBB.

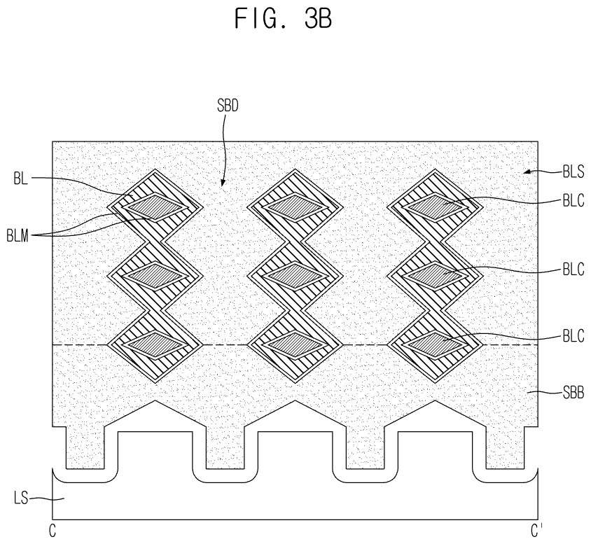

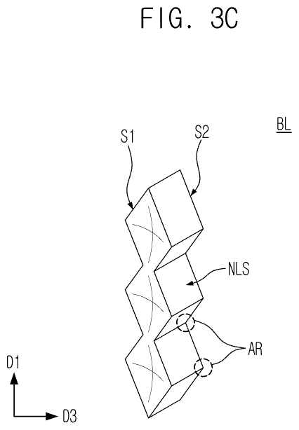

FIG. 3A is a perspective view illustrating the supporter structure BLS illustrated in FIG. 2A. FIG. 3B is a cross-sectional view of an array of the second conductive lines BL. FIG. 3C is a perspective view illustrating the second conductive line BL.

Referring to FIGS. 2A, 3A, 3B and 3C, the supporter structure BLS may include support bodies SBD vertically oriented from the bottom isolation portion SBB, outer support spacers BR1, inner support spacers BR2, and a plurality of support openings SVL. The support bodies SBD may be vertically oriented. The support bodies SBD may be horizontally adjacent to each other and may be interconnected by the outer support spacers BR1 and the inner support spacers BR2. The second conductive lines BL may be disposed in the support openings SVL. Specifically, the second conductive lines BL may be embedded in the support openings SVL of the supporter structure BLS. The second conductive lines BL may be referred to as “embedded second conductive lines BL”. Each of the support bodies SBD may be disposed between the second conductive lines BL that are horizontally adjacent to each other, and thus, the second conductive lines BL that are horizontally adjacent to each other may be electrically isolated by the support bodies SBD. The support openings SVL may be referred to as “vertical openings”, “support recesses”, or “support trenches”.

The bottom isolation portion SBB may be greater than the support bodies SBD. For example, a first vertical height H1 of the bottom isolation portion SBB may be greater than a second vertical height H2 of each of the support bodies SBD. The bottom isolation portion SBB, which has an integral structure of a dielectric material, may extend in the third direction D3 and may be coupled in common to the second conductive lines BL. The bottom isolation portion SBB, the support bodies SBD, the outer support spacers BR1 and the inner support spacers BR2 may be made of the same material. A combination of the bottom isolation portion SBB, the support bodies SBD, the outer support spacers BR1 and the inner support spacers BR2 may have an integral structure without a physical interface.

The dummy dielectric layers DIL may be formed to be horizontally adjacent to the bottom isolation portion SBB. Vertical heights of the dummy dielectric layers DIL may be greater than vertical heights of the inter-cell dielectric layers IL. The dummy spacers DSP may be formed on one side of the dummy dielectric layers DIL. The dummy conductive lines WLL may contact lower surfaces of the dummy dielectric layers DIL.

Referring to FIGS. 3A, 3B and 3C, the second conductive line BL may surround the first contact nodes BLC which are arranged in the first direction D1. The barrier layer BLM may be formed on an outer wall of the second conductive line BL and may also surround the first contact nodes BLC.

Each of the second conductive lines BL may include an outer side portion S1, an inner side portion S2, and non-linear side walls NLS. The non-linear side walls NLS of the second conductive line BL may include a plurality of angled corners AR. The outer side portions S1 of the second conductive lines BL may contact the outer support spacers BR1 of the supporter structure BLS. The inner side portions S2 of the second conductive lines BL may contact the inner support spacers BR2 of the supporter structure BLS. The outer support spacers BR1 of the supporter structure BLS may partially expose surfaces of the outer side portions S1 of the second conductive lines BL. The inner support spacers BR2 of the supporter structure BLS may partially expose surfaces of the inner side portions S2 of the second conductive lines BL. The exposed surfaces of the inner side portions S2 of the second conductive lines BL may be electrically coupled to the first doped regions SR through the barrier layers BLM and the first contact nodes BLC.

As described above, the second conductive lines BL may be embedded in the supporter structure BLS, and bottom portions of the second conductive lines BL may be isolated from each other by the bottom isolation portion SBB. The bottom isolation portion SBB may prevent bridging of the second conductive lines BL that are horizontally adjacent to each other. In addition, the second conductive lines BL may be sufficiently isolated from the lower structure LS by the bottom isolation portion SBB and the dummy structure DMS. The bottom isolation portion SBB may serve as a blocking layer that prevents the bottom portions of the second conductive lines BL from coming into contact with the lower structure LS.

The semiconductor device 100V may include a vertical arrangement VA of nano sheets HL. Each nano sheet HL includes the first doped region SR, the second doped region DR, and a channel CH positioned between them. The device also includes a vertical arrangement VA of switching elements TR. These elements TR have first conductive lines WL that surround the channels CH of the nano sheets HL. A supporter structure BLS is located adjacent to the first doped regions SR of the nano sheets HL in the vertical arrangement VA. Embedded within this support structure BLS are second conductive lines BL. These lines BL are coupled in common to the first doped regions SR of the nano sheets HL. Lastly, data storage elements CAP are connected to the second doped regions DR of the nano sheets HL.

The semiconductor device 100V may include the vertical arrangement VA of the switching elements TR each having a first edge and a second edge, the supporter structure BLS adjacent to the switching elements TR, the second conductive lines BL embedded in the supporter structure BLS and coupled in common to the first edges of the switching elements TR, and the data storage elements CAP each coupled to a different one of the second edges of the switching elements TR. The switching elements TR may include the nano sheets HL and the first conductive lines WL each having a gate-all-around structure of surrounding the channels CH of the nano sheets HL. The nano sheets HL may each include the first doped region SR, the second doped region DR, and the channel CH between the first doped region SR and the second doped region DR. The first and second edges of the switching elements TR may include the first doped region SR and the second doped region DR, respectively.

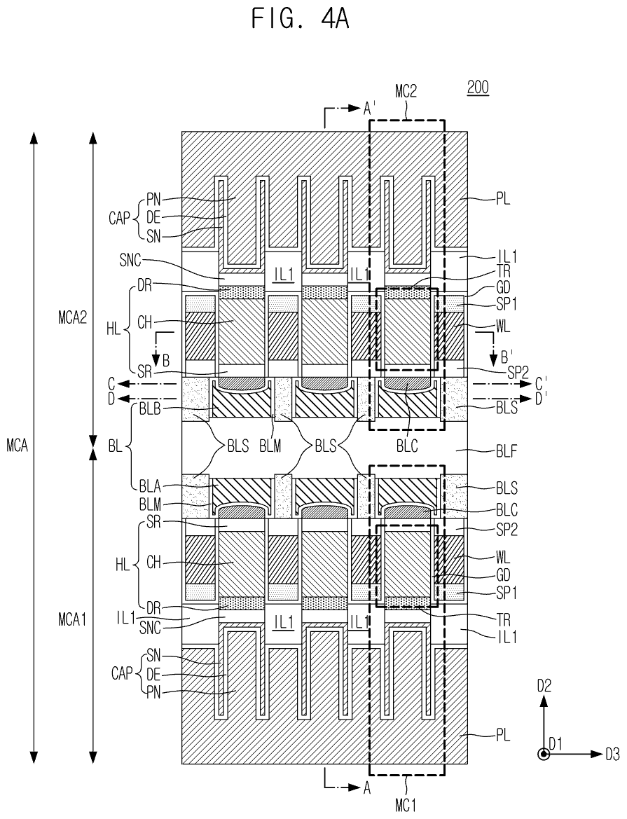

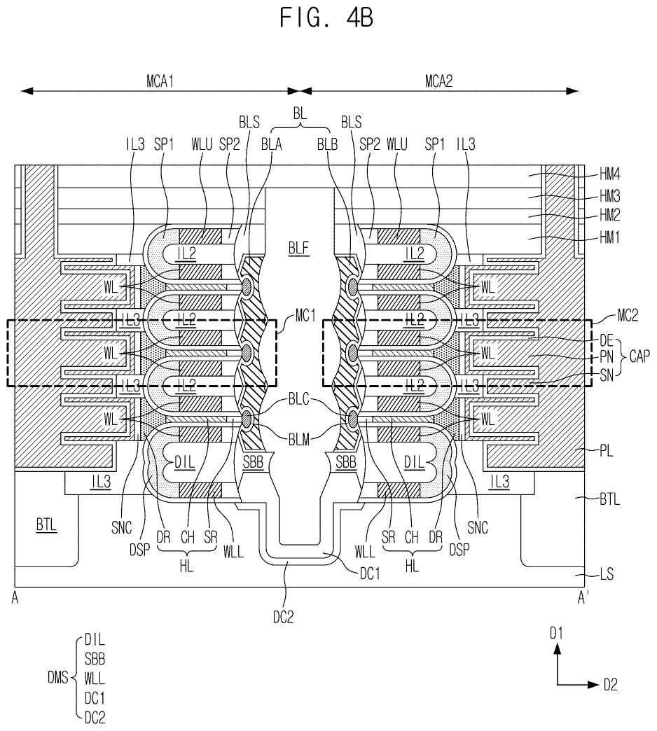

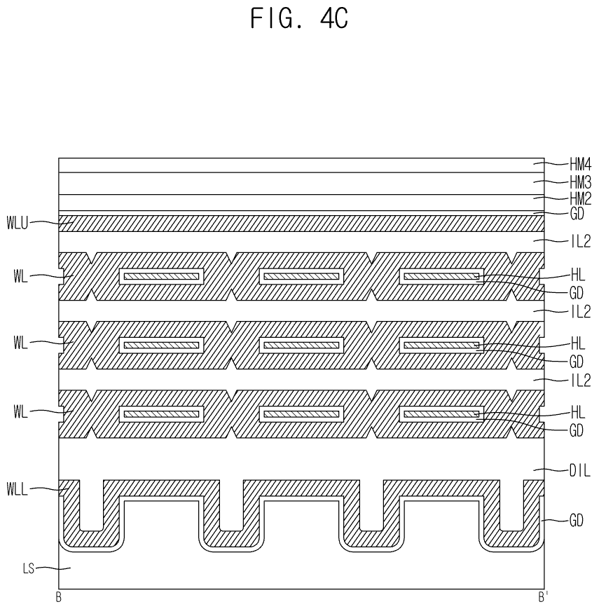

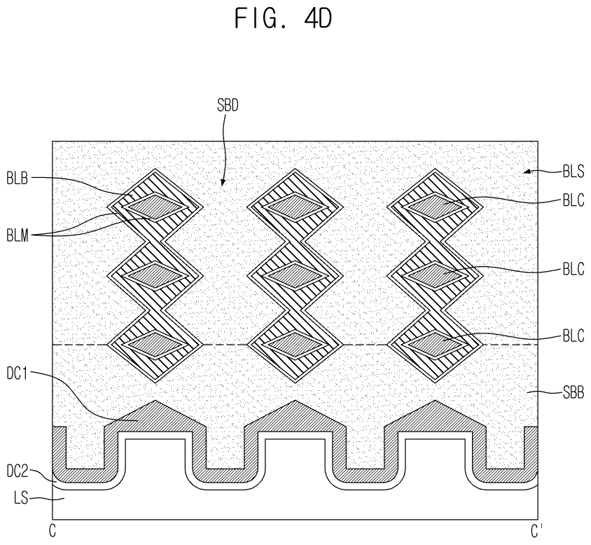

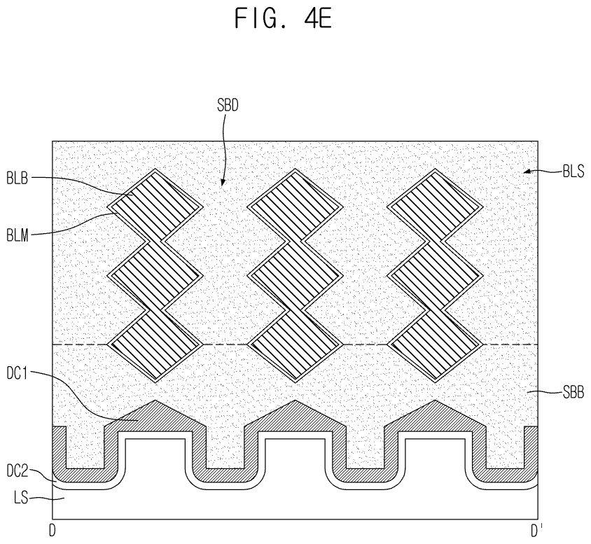

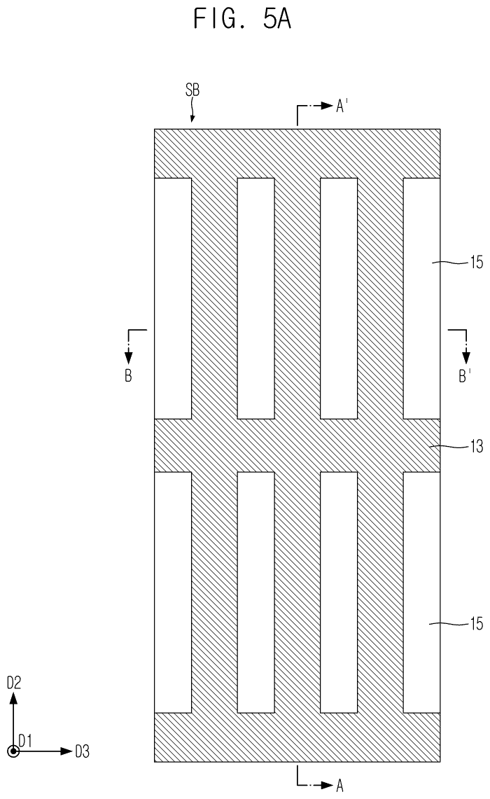

FIG. 4A is a schematic perspective view illustrating a semiconductor device 200 in accordance with an embodiment of the present disclosure. FIG. 4B is a schematic cross-sectional view of the semiconductor device 200 taken along line A-A′ illustrated in FIG. 4A. FIG. 4C is a schematic cross-sectional view of the semiconductor device 200 taken along line B-B′ illustrated in FIG. 4A. FIG. 4D is a schematic cross-sectional view of the semiconductor device 200 taken along line C-C′ illustrated in FIG. 4A. FIG. 4E is a schematic cross-sectional view of the semiconductor device 200 taken along line D-D′ illustrated in FIG. 4A. Detailed descriptions of overlapping components are provided above with reference to FIGS. 1A to 2E.

Referring to FIGS. 4A to 4E, the semiconductor device 200 may include a lower structure LS and a memory cell array MCA disposed over the lower structure LS.

The lower structure LS may include a substrate. The lower structure LS may be a material appropriate for semiconductor processing. The lower structure LS may include a semiconductor substrate, a conductive material, a dielectric material, a semiconductive material, or a combination thereof. The lower structure LS may include silicon, monocrystalline silicon, polysilicon, amorphous silicon, silicon germanium, monocrystalline silicon germanium, polycrystalline silicon germanium, carbon-doped silicon, epitaxial silicon, a combination thereof, or multilayers thereof. The lower structure LS may also include another semiconductor material such as germanium. The lower structure LS may also include a III-V group semiconductor substrate, for example, a compound semiconductor substrate such as GaAs. In some embodiments, the lower structure LS may include a metal wiring structure, a dielectric structure, a conductive structure, a bonding pad structure, another memory, or a peripheral circuit portion. For example, the lower structure LS may include a structure in which the peripheral circuit portion, the metal wiring structure and the bonding pad structure are sequentially stacked. The memory cell array MCA and the peripheral circuit portion of the lower structure LS may be bonded. Any suitable wafer bonding may be used for bonding the lower structure LS and memory cell array. For example, the wafer bonding may include pad bonding, hybrid bonding, oxide-to-oxide bonding, metal-to-metal bonding, or a combination thereof.

The memory cell array MCA may include a plurality of memory cells, for example, a plurality of first memory cells MC1 and a plurality of second memory cells MC2. The second memory cells MC2 may be stacked vertically in a first direction D1 over corresponding first memory cells MC1. The memory cell array MCA may include a three-dimensional array of the memory cells MC1 and MC2. Each of the memory cells MC1 and MC2 may include a switching element TR and a data storage element CAP. The switching element TR may include a first conductive line WL, a nano sheet dielectric layer GD, and a nano sheet HL. The nano sheet HL may include a first doped region SR, a channel CH, and a second doped region DR. A first contact node BLC and a barrier layer BLM may be formed between the first doped region SR of the nano sheet HL and a second conductive line BL. A second contact node SNC may be formed between the second doped region DR of the nano sheet HL and the data storage element CAP. The nano sheet HL may be surrounded by the nano sheet dielectric layer GD. The first conductive line WL may extend in a third direction D3 while surrounding the channels CH of the nano sheets HL on the nano sheet dielectric layer GD.

The memory cells MC1 and MC2 may each have the same configuration as the memory cell MC described above with reference to FIGS. 1A and 1B.

The memory cell array MCA may include a first sub-cell array MCA1 and a second sub-cell array MCA2. The first sub-cell array MCA1 may include a three-dimensional array of the first memory cells MC1. The second sub-cell array MCA2 may include a three-dimensional array of the second memory cells MC2. The first memory cells MC1 of the first sub-cell array MCA1 may share a first vertical conductive line BLA. The second memory cells MC2 of the second sub-cell array MCA2 may share a second vertical conductive line BLB. From the perspective of a top view, the first and second vertical conductive lines BLA and BLB may each have a rectangular shape. A bottom portion of the first vertical conductive line BLA may be electrically isolated from a bottom portion of the second vertical conductive line BLB.

Each of the first memory cells MC1 of the first sub-cell array MCA1 may include the first vertical conductive line BLA, the switching element TR, and the data storage element CAP. The switching element TR may include the first conductive line WL and the nano sheet HL. The switching elements TR of the first memory cells MC1 may be nano sheet transistors. The first sub-cell array MCA1 may include a horizontal arrangement and a vertical arrangement of the nano sheet transistors. The first sub-cell array MCA1 may include a horizontal arrangement of first vertical conductive lines BLA. The first sub-cell array MCA1 may include a horizontal arrangement and a vertical arrangement of first conductive lines WL. The first sub-cell array MCA1 may include a horizontal arrangement and a vertical arrangement of data storage elements CAP.

The nano sheet HL of each of the first memory cells MC1 may include a first edge and a second edge. The first edge of the nano sheet HL may refer to a portion of the first doped region SR that is electrically coupled to the first vertical conductive line BLA. The second edge of the nano sheet HL may refer to a portion of the second doped region DR electrically coupled to a first electrode SN of the data storage element CAP.

The first memory cell MC1 may further include the first contact node BLC and the second contact node SNC. The first contact node BLC may be disposed between the first vertical conductive line BLA and the nano sheet HL. The first contact node BLC may be selectively grown from the first edge of the nano sheet HL. The first contact node BLC may be formed by selective epitaxial growth (SEG). For example, the first contact node BLC may be a silicon epitaxial layer formed by the SEG. The first contact node BLC may be a doped silicon epitaxial layer. The second contact node SNC may be selectively grown from the second edge of the nano sheet HL. The second contact node SNC may be formed by the SEG. For example, the second contact node SNC may be a silicon epitaxial layer formed by the SEG. The second contact node SNC may be a doped silicon epitaxial layer. The first memory cell MC1 may further include the barrier layer BLM between the first contact node BLC and the second conductive line BL. The barrier layer BLM may include metal nitride, such as titanium nitride. In some embodiments, the first memory cell MC1 may further include an ohmic contact layer (Not Shown) between the barrier layer BLM and the first contact node BLC. The ohmic contact layer may include a metal silicide. Referring back to FIG. 4D, the second vertical conductive line BLB may surround the first contact nodes BLC arranged in the first direction D1. The barrier layer BLM may be formed on an outer wall of the second vertical conductive line BLB while surrounding the first contact nodes BLC.

The first memory cell MC1 may further include a first spacer SP1 and a second spacer SP2. The first spacer SP1 may be disposed between the first conductive line WL and the second doped region DR. The second spacer SP2 may be disposed between the first conductive line WL and the second conductive line BL. The first and second spacers SP1 and SP2 may each include a dielectric material. The first and second spacers SP1 and SP2 may each include silicon oxide, silicon nitride, or a combination thereof. The first spacer SP1 may surround the second doped region DR of the nano sheet HL, and the second spacer SP2 may surround the first doped region SR of the nano sheet HL. The first and second spacers SP1 and SP2 may be disposed on both sidewalls of the first conductive line WL. That is, the first and second spacers SP1 and SP2 may extend in the third direction D3.

Each of the second memory cells MC2 of the second sub-cell array MCA2 may include the second vertical conductive line BLB, the switching element TR, and the data storage element CAP. The switching element TR may include the first conductive line WL and the nano sheet HL. The switching elements TR of the second memory cells MC2 may be nano sheet transistors. The second sub-cell array MCA2 may include a horizontal arrangement and a vertical arrangement of the nano sheet transistors. The second sub-cell array MCA2 may include a horizontal arrangement of second vertical conductive lines BLB. The second sub-cell array MCA2 may include a horizontal arrangement and a vertical arrangement of first conductive lines WL. The second sub-cell array MCA2 may include a horizontal arrangement and a vertical arrangement of data storage elements CAP.

The nano sheet HL of the second memory cell MC2 may include a first edge and a second edge. The first edge of the nano sheet HL may refer to a portion of the first doped region SR electrically coupled to the second vertical conductive line BLB, and the second edge of the nano sheet HL may refer to a portion of the second doped region DR electrically coupled to a first electrode SN of the data storage element CAP.

The second memory cell MC2 may further include the first contact node BLC and the second contact node SNC. The first contact node BLC may be disposed between the second vertical conductive line BLB and the nano sheet HL. The first contact node BLC may be selectively grown from the first edge of the nano sheet HL. The first contact node BLC may be formed by selective epitaxial growth (SEG). For example, the first contact node BLC may be a silicon epitaxial layer formed by the SEG. The first contact node BLC may be a doped silicon epitaxial layer. The second contact node SNC may be selectively grown from the second edge of the nano sheet HL. The second contact node SNC may be formed by the SEG. For example, the second contact node SNC may be a silicon epitaxial layer formed by the SEG. The second contact node SNC may be a doped silicon epitaxial layer. The second memory cell MC2 may further include the barrier layer BLM between the first contact node BLC and the second conductive line BL. The barrier layer BLM may include metal nitride, such as titanium nitride. In some embodiments, the second memory cell MC2 may further include an ohmic contact layer (Not Shown) between the barrier layer BLM and the first contact node BLC. The ohmic contact layer may include metal silicide.

The second memory cell MC2 may further include a first spacer SP1 and a second spacer SP2. The first spacer SP1 may be disposed between the first conductive line WL and the second doped region DR. The second spacer SP2 may be disposed between the first conductive line WL and the second conductive line BL. The first and second spacers SP1 and SP2 may each include a dielectric material. The first and second spacers SP1 and SP2 may each include silicon oxide, silicon nitride, or a combination thereof. The first spacer SP1 may surround the second doped region DR of the nano sheet HL, and the second spacer SP2 may surround the first doped region SR of the nano sheet HL. The first and second spacers SP1 and SP2 may be disposed on both sidewalls of the first conductive line WL. That is, the first and second spacers SP1 and SP2 may extend in the third direction D3.

The first contact nodes BLC of the first and second memory cells MC1 and MC2 may be narrower sheet-side contact nodes, and the second contact nodes SNC of the first and second memory cells MC1 and MC2 may be wider sheet-side contact nodes.

As described above, the first vertical conductive line BLA and the second vertical conductive line BLB may vertically extend in the first direction D1, the nano sheets HL may extend in a second direction D2, and the first conductive lines WL may horizontally extend in the third direction D3.

Referring back to FIGS. 4A, 4B and 4C, each of the first inter-cell dielectric layers IL1 may be disposed between the data storage elements CAP adjacent to each other in the third direction D3. Each of second inter-cell dielectric layers IL2 may be disposed between the first conductive lines WL vertically stacked in the first direction D1. Each of third inter-cell dielectric layers IL3 may be disposed between first electrodes SN of the data storage elements CAP vertically stacked in the first direction D1. The first to third inter-cell dielectric layers IL1, IL2 and IL3 may each include silicon oxide, silicon carbon oxide (SiCO), silicon nitride, or a combination thereof. The first inter-cell dielectric layers IL1 may be referred to as “device isolation layers”.

The memory cell array MCA may include a plurality of first conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of second conductive lines BL spaced apart in the third direction D3. The memory cell array MCA may include a dummy conductive line WLU (see FIG. 4B) disposed at a level higher than an uppermost first conductive line WL and a dummy conductive line WLL disposed at a level lower than a lowermost first conductive line WL. The dummy conductive lines WLU and WLL may each have a linear shape extending horizontally.

The memory cell array MCA may include a stack of a plurality of hard mask layers, for example, hard mask layers HM1, HM2, HM3 and HM4. The hard mask layers may be disposed, for example, at a level higher than the uppermost first conductive line WL.

The memory cell array MCA may include a plurality of bottom protection layers BTL. The bottom protection layers BTL may prevent a lowermost data storage element CAP and the lower structure LS from coming into electrical contact with each other. The bottom protection layers BTL may each include a dielectric material.

An array isolation layer BLF may be disposed between the first vertical conductive line BLA and the second vertical conductive line BLB. The array isolation layer BLF may include a dielectric material.

The nano sheets HL of the switching elements TR horizontally disposed in the third direction D3 may share one first conductive line WL. The nano sheets HL of the switching elements TR horizontally disposed in the third direction D3 may be coupled to different second conductive lines BL. The switching elements TR stacked in the first direction D1 may share one second conductive line BL. The switching elements TR horizontally disposed in the third direction D3 may share one first conductive line WL.

Second electrodes PN of the data storage elements CAP may be coupled to a common plate PL.

The semiconductor device 200 may further include supporter structures BLS disposed over the lower structure LS. The supporter structures BLS may support the first and second vertical conductive lines BLA and BLB of the memory cell array MCA. The first and second sub-cell arrays MCA1 and MCA2 may each include the supporter structures BLS.

The supporter structure BLS of the first sub-cell array MCA1 and the supporter structure BLS of the second sub-cell array MCA2 may be isolated from each other. The array isolation layer BLF may be disposed between the supporter structure BLS of the first sub-cell array MCA1 and the supporter structure BLS of the second sub-cell array MCA2. The supporter structure BLS of the first sub-cell array MCA1 and the supporter structure BLS of the second sub-cell array MCA2 may be isolated from each other by the array isolation layer BLF.

The supporter structures BLS of the first and second sub-cell arrays MCA1 and MCA2 may include bottom isolation portions SBB, support bodies SBD vertically oriented from the bottom isolation portion SBB, outer support spacers BR1, inner support spacers BR2, and a plurality of support openings SVL, as described above with reference to FIG. 3A. The first and second vertical conductive lines BLA and BLB may be embedded in the support openings SVL of the supporter structures BLS. The first vertical conductive lines BLA of the first sub-cell array MCA1 may be isolated from each other by the support bodies SBD of the supporter structure BLS. The second vertical conductive lines BLB of the second sub-cell array MCA2 may be isolated from each other by the support bodies SBD of the supporter structure BLS.

The first and second sub-cell arrays MCA1 and MCA2 may each include the bottom isolation portion SBB. The array isolation layer BLF may be formed between the bottom isolation portion SBB of the first sub-cell array MCA1 and the bottom isolation portion SBB of the second sub-cell array MCA2.

Bottom portions of the first vertical conductive lines BLA of the first sub-cell array MCA1 may be isolated from the lower structure LS by the bottom isolation portion SBB. Also, bottom portions of the second vertical conductive lines BLB of the second sub-cell array MCA2 may be isolated from the lower structure LS by the bottom isolation portion SBB.

Each of the supporter structures BLS of the first and second sub-cell arrays MCA1 and MCA2 may have an integral structure also referred to as a continuous structure. The supporter structures BLS may each include an integral structure of a dielectric material. The supporter structures BLS may each include a low-k material, silicon oxide, silicon carbon oxide, silicon nitride, an air gap, or a combination thereof.

Dummy structures DMS may be disposed adjacent to the bottom isolation portions SBB. The dummy structures DMS may include dummy dielectric layers DIL, dummy spacers DSP, and dummy conductive lines WLL. The dummy structures DMS may further include a dummy contact node DC1 and a dummy doped region DC2. The dummy dielectric layers DIL may be formed horizontally adjacent to the bottom isolation portions SBB. Vertical heights of the dummy dielectric layers DIL may be greater than vertical heights of the second inter-cell dielectric layers IL2. The dummy spacers DSP may be formed on one side of the dummy dielectric layers DIL. The dummy conductive lines WLL may contact lower surfaces of the dummy dielectric layers DIL. The dummy contact node DC1 may be disposed below the bottom isolation portions SBB. The dummy contact node DC1 may have a U shape. The dummy contact node DC1 may be formed below the bottom isolation portions SBB, and the dummy doped region DC2 may be formed in a surface of the lower structure LS in contact with the dummy contact node DC1. Vertical heights of the dummy structures DMS may be greater than vertical heights of the first and second memory cells MC1 and MC2.

As described above, the first and second vertical conductive lines BLA and BLB may be embedded in the supporter structures BLS, and bottom portions of the first and second vertical conductive lines BLA and BLB may be isolated from each other by the bottom isolation portions SBB. The first and second vertical conductive lines BLA and BLB and the lower structure LS may be spaced apart by the bottom isolation portions SBB and the dummy structures DMS. In addition, bridging of the first vertical conductive line BLA and the second vertical conductive line BLB may be prevented by the bottom isolation portions SBB and the array isolation layer BLF.

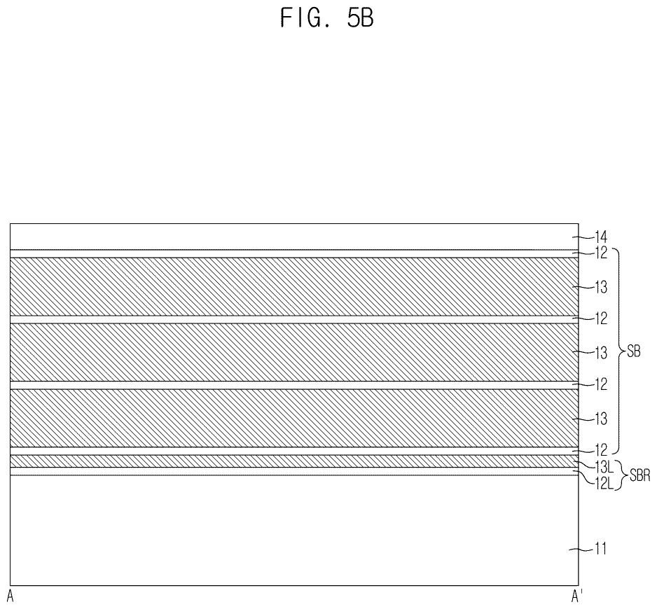

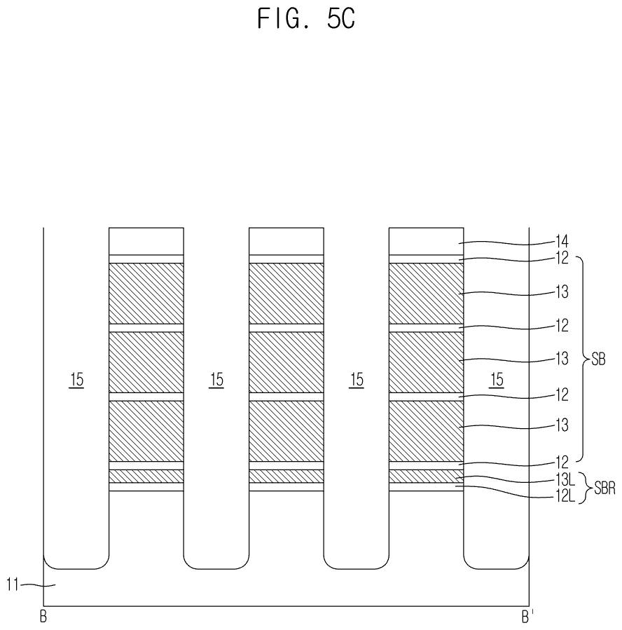

FIGS. 5A to 25B illustrate various views of a semiconductor device formed utilizing a method for fabricating the semiconductor device in accordance with an embodiment of the present disclosure.

FIG. 5A is a plan view illustrating a structure at a mold layer level for describing a method of forming a mold stack SB. FIG. 5B is a cross-sectional view of the structure taken along line A-A′ illustrated in FIG. 5A. FIG. 5C is a cross-sectional view of the structure taken along line B-B′ illustrated in FIG. 5A.

Referring to FIGS. 5A to 5C, a dummy mold SBR may be formed on a substrate 11. The mold stack SB may be formed over the dummy mold SBR. The mold stack SB may include an alternating stack of sacrificial mold layers 12 and mold layers 13.

The substrate 11 may be a material appropriate for semiconductor processing. The substrate 11 may include a semiconductor substrate, a conductive material, a dielectric material, a semiconductive material, or a combination thereof. The substrate 11 may include silicon, monocrystalline silicon, polysilicon, amorphous silicon, silicon germanium, monocrystalline silicon germanium, polycrystalline silicon germanium, carbon-doped silicon, epitaxial silicon, a combination thereof, or multilayers thereof. The substrate 11 may also include another semiconductor material such as germanium. The substrate 11 may also include a III-V group semiconductor substrate, for example, a compound semiconductor substrate such as Gallium Arsenide (GaAs). The mold stack SB may include an alternating stack of the sacrificial mold layers 12 and the mold layers 13.

To form the mold stack SB, the sacrificial mold layers 12 may be alternately stacked with the mold layers 13, and the first mold layers 12 and the second mold layers 13 may be epitaxially grown.

The sacrificial mold layers 12 and the mold layers 13 may be different semiconductive materials. For example, the sacrificial mold layers 12 may each include silicon germanium or monocrystalline silicon germanium. Also, as an example, the mold layers 13 may each include monocrystalline silicon. The sacrificial mold layers 12 and the mold layers 13 may be formed by an epitaxial growth process. A lowermost sacrificial mold layer 12 may serve as a seed layer during the epitaxial growth process. Each of the sacrificial mold layers 12 may be thinner than each of the mold layers 13. The sacrificial mold layers 12 may include first epitaxially grown layers, and the mold layers 13 may include second epitaxially grown layers.

In an embodiment, a plurality of monocrystalline silicon germanium layers may be alternately stacked with a plurality of monocrystalline silicon layers in the mold stack SB. For example, the sacrificial mold layers 12 may be the monocrystalline silicon germanium layers, and the mold layers 13 may be the monocrystalline silicon layers. A stack of a monocrystalline silicon germanium layer and a monocrystalline silicon layer (a SiGe/Si stack) may be stacked multiple times. The sacrificial mold layers 12 may be referred to as “sacrificial layers”, and the mold layers 13 may be referred to as “nano sheet target layers” or “recess target layers”.

The mold stack SB may be referred to as a “vertical stack”. The mold stack SB may be formed by alternately stacking a plurality of sacrificial layers and a plurality of nano sheet target layers. The sacrificial layers may be monocrystalline silicon germanium layers, and the nano sheet target layers may be monocrystalline silicon layers.

A thickness ratio of the sacrificial mold layers 12 and a thickness ratio of the mold layers 13 in the mold stack SB may be variously modified. For example, the thickness of each of the sacrificial mold layers 12 may be 5 to 20 nm, and the thickness of each of the mold layers 13 may be 50 to 80 nm. Furthermore, the number (or quantity) of the sacrificial mold layers 12 and the number (or quantity) of the mold layers 13 in the mold stack SB may be variously modified.

In an embodiment, the dummy mold SBR may be formed between the substrate 11 and the mold stack SB. The dummy mold SBR may include a stack of a first dummy mold layer 12L and a second dummy mold layer 13L. The first dummy mold layer 12L and the sacrificial mold layers 12 may be the same material, and the second dummy mold layer 13L and the mold layers 13 may be made of the same material. The second dummy mold layer 13L may be thinner than the mold layers 13. The first dummy mold layer 12L and the sacrificial mold layers 12 may have the same thickness.

In some embodiments, the thicknesses and an alternating quantity of the first dummy mold layer 12L and second dummy mold layer 13L used as the dummy mold SBR may be variously modified. For example, the first dummy mold layer 12L may be formed with a thickness of 10 nm, and the second dummy mold layer 13L may be formed with a thickness of 40 nm. For example, the first dummy mold layer 12L may be formed with a thickness of 20 nm, and the second dummy mold layer 13L may be formed with a thickness of 40 nm. For example, the dummy mold SBR may be formed with a four-layer structure of the first dummy mold layer 12L, the second dummy mold layer 13L, the first dummy mold layer 12L and the second dummy mold layer 13L. In this case, the first dummy mold layer 12L may be formed with a thickness of 10 nm, and the second dummy mold layer 13L may be formed with a thickness of 20 nm. To form the dummy mold SBR, the first dummy mold layer 12L and the second dummy mold layer 13L may be formed alternately at least once. A size of a dummy recess formed subsequently may be controlled depending on the thicknesses and alternating quantity of the first dummy mold layer 12L and second dummy mold layer 13L.

A first hard mask layer 14 may be formed on the mold stack SB. The first hard mask layer 14 may include a dielectric material such as an oxide-based material, a nitride-based material, a carbon-based material, or a combination thereof. For example, the first hard mask layer 14 may include silicon oxide (SiO₂), silicon nitride (Si₃N₄) amorphous carbon, or a combination thereof.

Subsequently, a plurality of sacrificial isolation openings 15 may be formed by etching portions of the mold stack SB and portions of the dummy mold SBR using the first hard mask layer 14 as a barrier. The sacrificial isolation openings 15 may be initial openings for cell isolation. From the perspective of a top view, cross-sections of the sacrificial isolation openings 15 may each have a rectangular shape. In some embodiments, the cross-sections of the sacrificial isolation openings 15 may each have a circular shape or an oval shape. In some embodiments, the sacrificial isolation openings 15 may be referred to as “sacrificial isolation trenches”. The sacrificial isolation openings 15 may vertically extend in a first direction D1 and extend lengthwise in a second direction D2. The sacrificial isolation openings 15 may be disposed at a predetermined interval in a third direction D3. Bottom surfaces of the sacrificial isolation openings 15 may extend inside of the substrate 11.

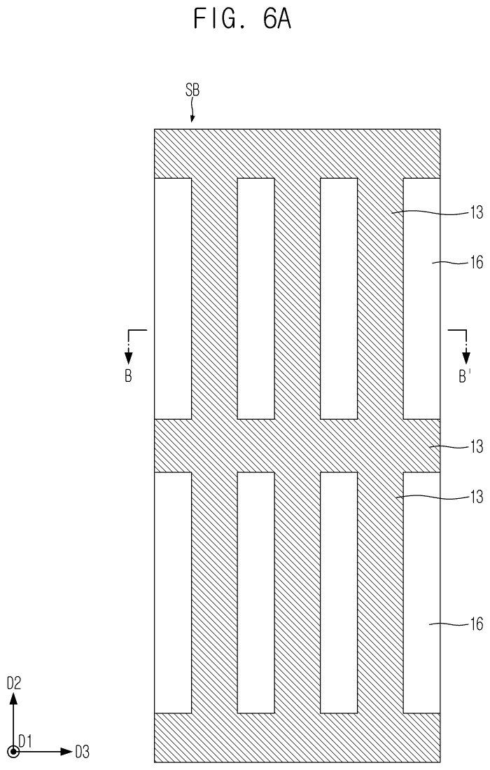

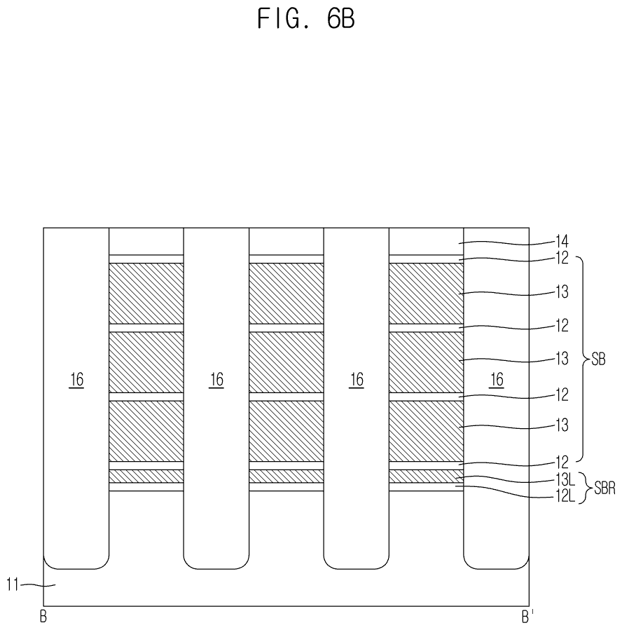

FIG. 6A is a plan view illustrating the structure at the mold layer level for describing a method of forming sacrificial isolation layers 16. FIG. 6B is a cross-sectional view of the structure taken along line B-B′ illustrated in FIG. 6A.

Referring to FIGS. 6A and 6B, the sacrificial isolation layers 16 may be formed by filling the sacrificial isolation openings 15. The sacrificial isolation layer 16 may include the same material. The sacrificial isolation 16 may be each form of a dielectric material. The sacrificial isolation layers 16 may have an etch selectivity with respect to the mold stack SB and the dummy mold SBR. For example, the sacrificial isolation layers 16 may each include silicon oxide, silicon nitride, silicon carbon oxide, silicon carbon nitride, or a combination thereof. Forming the sacrificial isolation layers 16 may include forming sacrificial isolation materials on the first hard mask layer 14 to fill the sacrificial isolation openings 15 and planarizing the sacrificial isolation materials so that a surface of the first hard mask layer 14 is exposed.

The sacrificial isolation layers 16 may vertically extend in the first direction D1 and extend lengthwise in the second direction D2. The sacrificial isolation layers 16 may be disposed at a predetermined interval in the third direction D3. The sacrificial isolation layers 16 may penetrate the mold stack SB and the dummy mold SBR in the first direction D1.

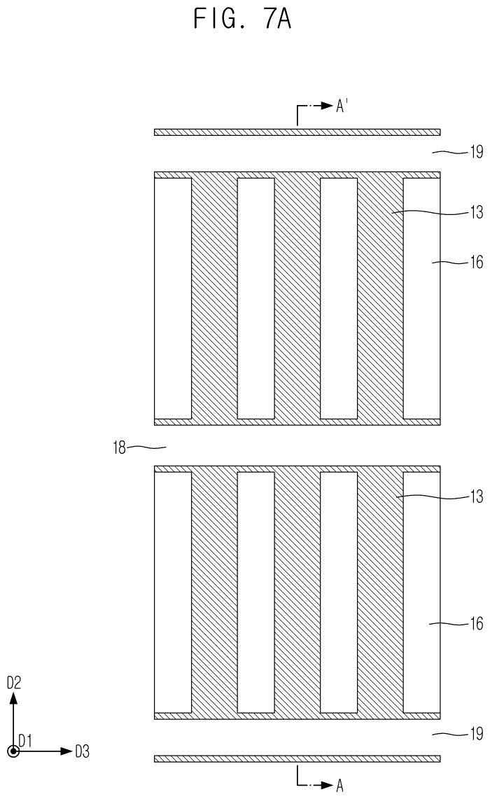

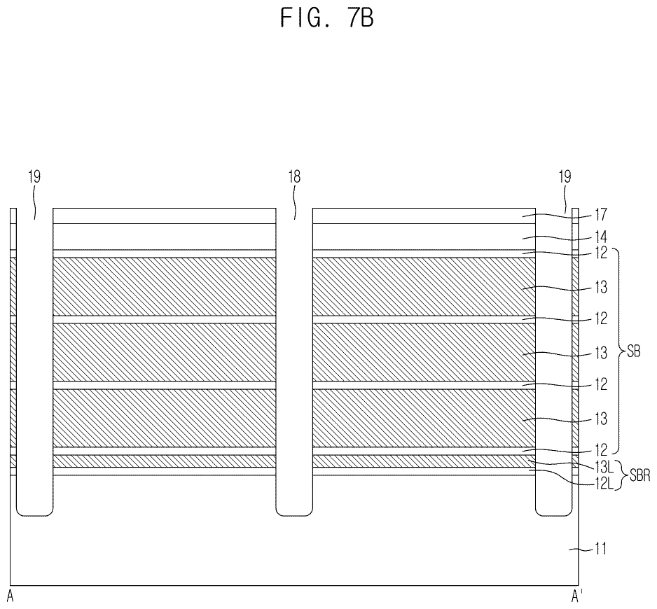

FIG. 7A is a plan view illustrating the structure at the mold layer level for describing a method of forming sacrificial linear openings 18 and 19. FIG. 7B is a cross-sectional view of the structure taken along line A-A′ illustrated in FIG. 7A.

Referring to FIGS. 7A and 7B, a second hard mask layer 17 may be formed on the mold stack SB and the sacrificial isolation layers 16. The second hard mask layer 17 may include a dielectric material such as an oxide-based material, a nitride-based material, a carbon-based material, or a combination thereof. For example, the second hard mask layer 17 may include SiO₂, Si₃N₄, amorphous carbon, or a combination thereof. The second hard mask layer 17 may be formed by etching a second hard mask material using a mask layer such as photoresist. The second hard mask layer 17 may have a plurality of line-shaped openings defined therein.

The mold stack SB and the dummy mold SBR may be etched using the second hard mask layer 17 as an etch barrier, and subsequently, a portion of the substrate 11 may be etched. Accordingly, a plurality of sacrificial linear openings 18 and 19 may be formed between the sacrificial isolation layers 16. The plurality of the sacrificial linear openings 18 and 19 may pass through the mold stack SB and the dummy mold SBR and extend partially into the substrate 11. The sacrificial linear openings may include a first sacrificial linear opening 18 and a second sacrificial linear opening 19. From the perspective of a top view, the first sacrificial linear opening 18 and the second sacrificial linear opening 19 may be line-shaped openings extending in the third direction D3. The first sacrificial linear opening 18 and the second sacrificial linear opening 19 may vertically extend in the first direction D1. The sacrificial isolation layers 16 may be disposed between the first sacrificial linear opening 18 and the second sacrificial linear opening 19 in the second direction D2. From the perspective of a top view, cross sections of the first and second sacrificial linear openings 18 and 19 may each have a rectangular shape. In some embodiments, the cross sections of the first and second sacrificial linear openings 18 and 19 may each have a circular shape or an oval shape. The first and second sacrificial linear openings 18 and 19 may each have a width in the second direction D2 which is less than a width in the third direction D3. The first and second sacrificial linear openings 18 and 19 may be referred to as “sacrificial linear trenches”. The sacrificial isolation layers 16 may not contact the first and second sacrificial linear openings 18 and 19.

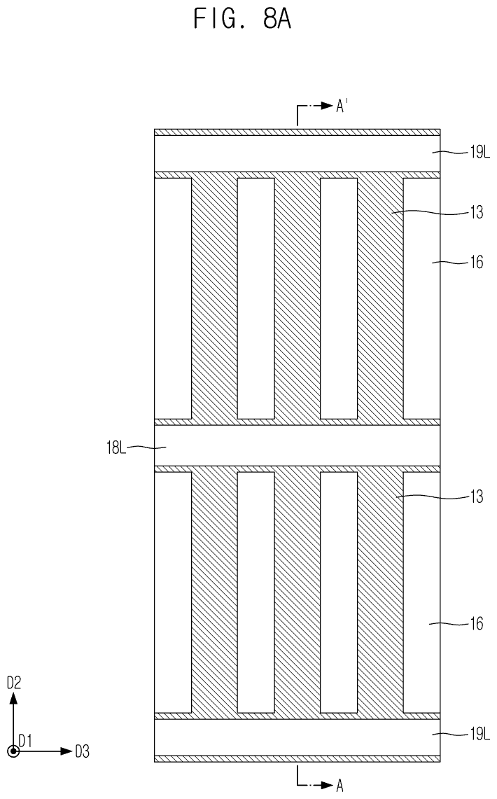

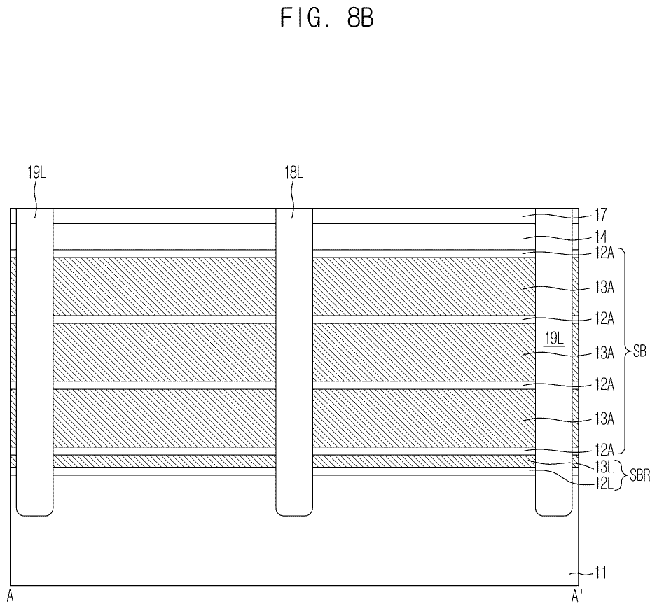

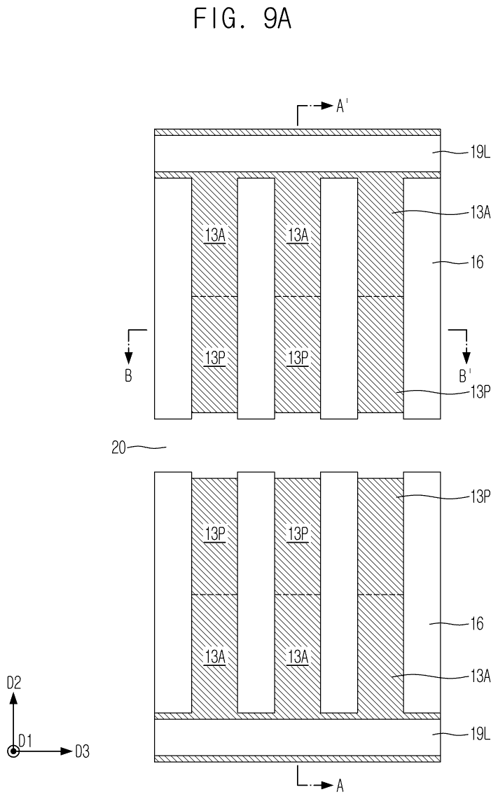

FIG. 8A is a plan view illustrating the structure at the mold layer level for describing a method of forming linear sacrificial layers 18L and 19L. FIG. 8B is a cross-sectional view of the structure taken along line A-A′ illustrated in FIG. 8A.

Referring to FIGS. 8A and 8B, the linear sacrificial layers 18L and 19L may be formed to fill the first and second sacrificial linear openings 18 and 19. The linear sacrificial layers may include a first linear sacrificial layer 18L and a second linear sacrificial layer 19L. From the perspective of a top view, the first linear sacrificial layer 18L and the second linear sacrificial layer 19L may have line shapes extending in the third direction D3. The first linear sacrificial layer 18L and the second linear sacrificial layer 19L may vertically extend in the first direction D1. The sacrificial isolation layers 16 may be disposed between the first linear sacrificial layer 18L and the second linear sacrificial layer 19L in the second direction D2. From the perspective of a top view, cross sections of the first and second linear sacrificial layers 18L and 19L may each have a rectangular shape. In some embodiments, the cross-sections of the first and second linear sacrificial layers 18L and 19L may each have a circular shape or an oval shape. The first and second linear sacrificial layers 18L and 19L may include the same material. The first and second linear sacrificial layers 18L and 19L may each be formed of a dielectric material. For example, the first and second linear sacrificial layers 18L and 19L may each include silicon oxide, silicon nitride, silicon carbon oxide, silicon carbon nitride, or a combination thereof. The sacrificial isolation layers 16 may not contact the first and second linear sacrificial layers 18L and 19L.

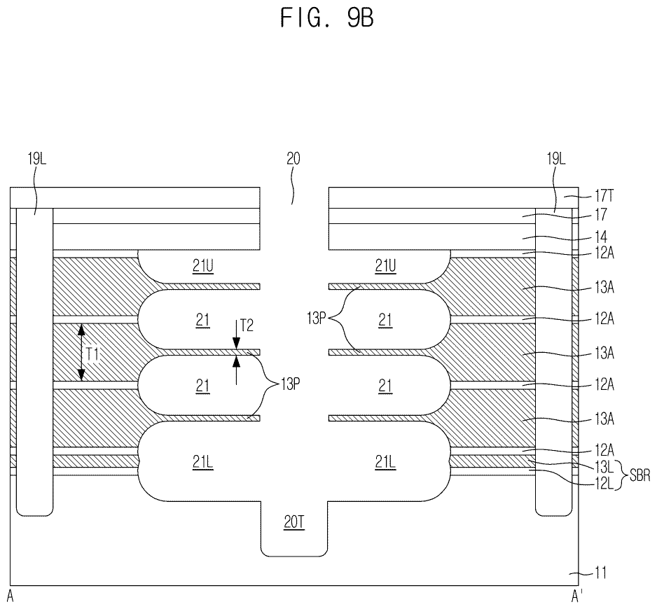

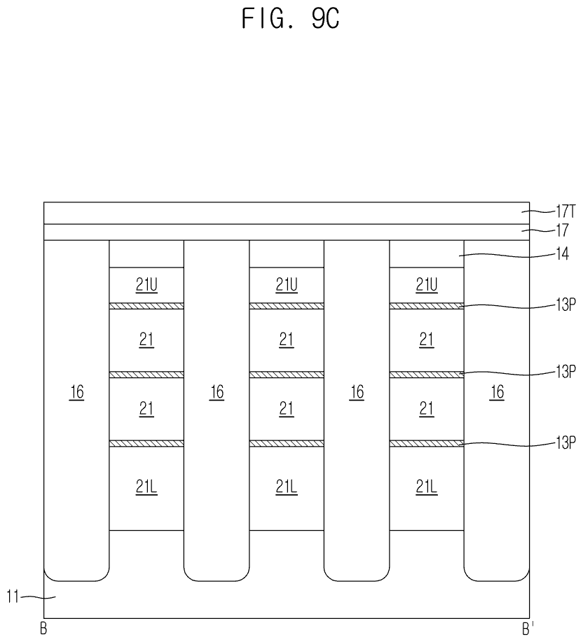

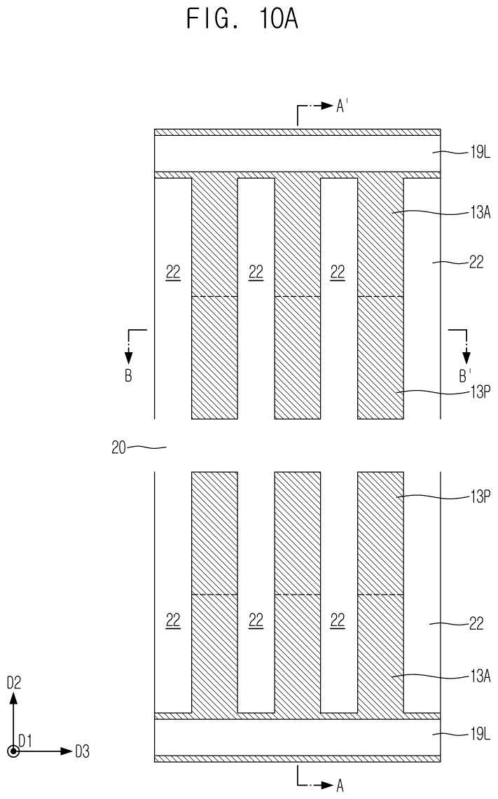

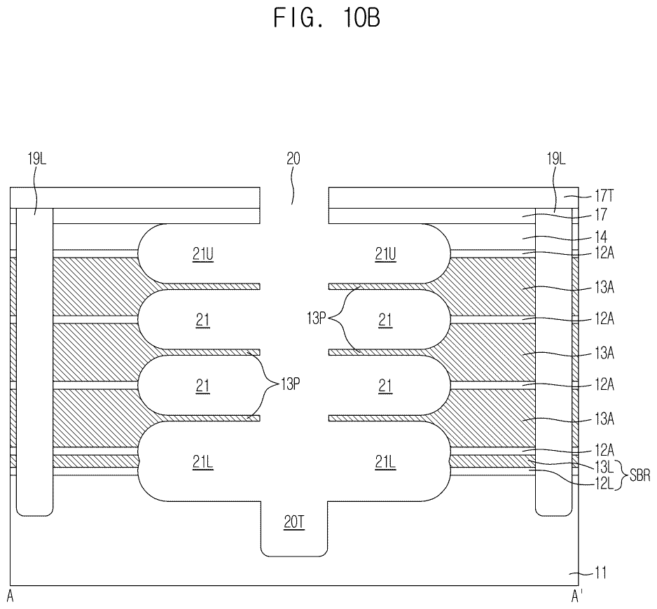

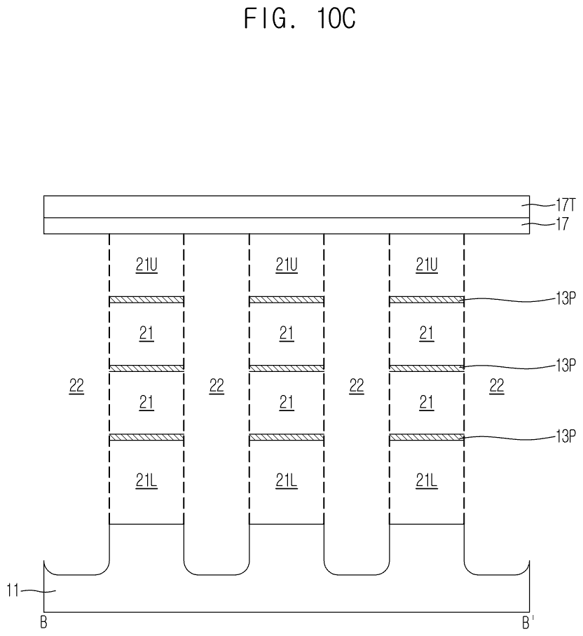

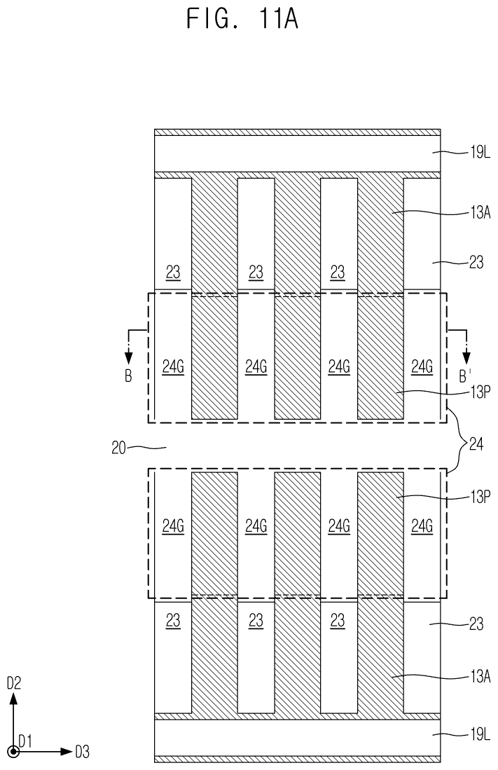

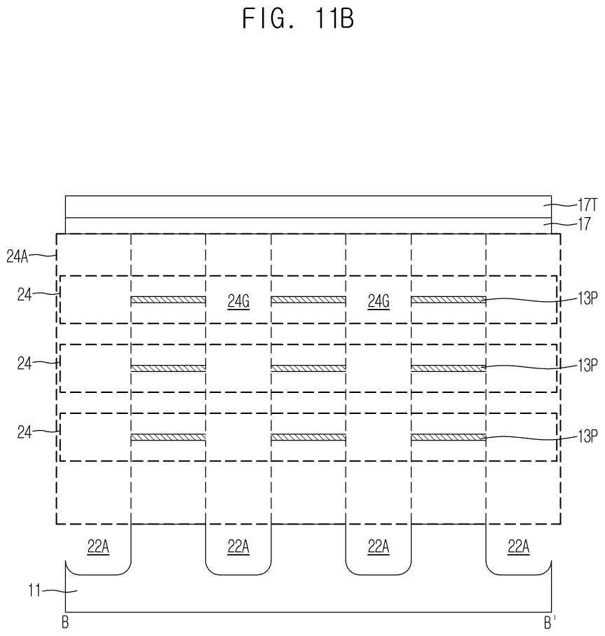

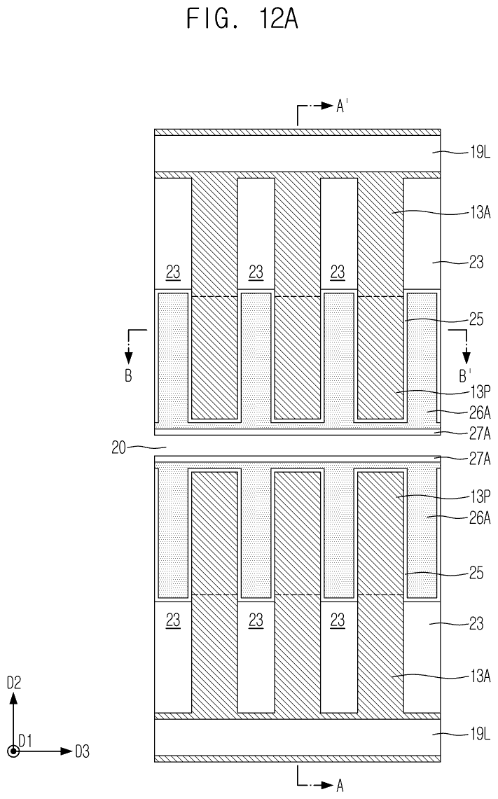

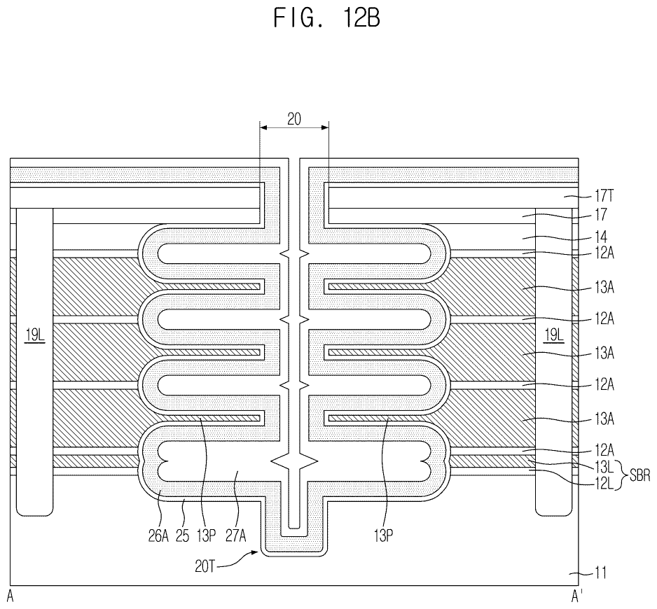

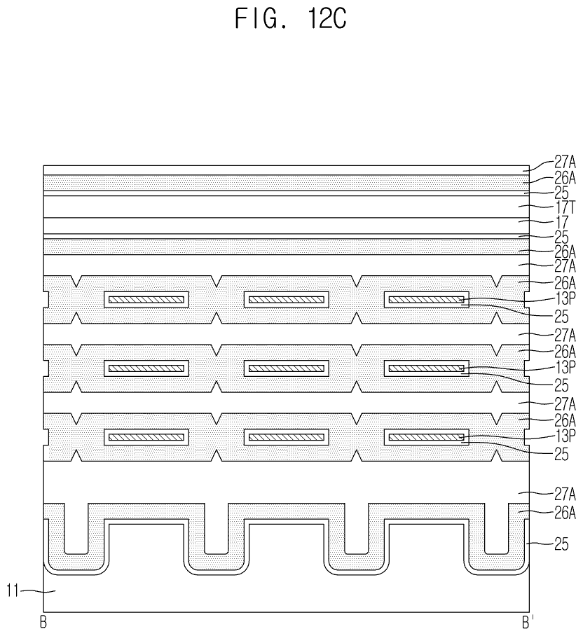

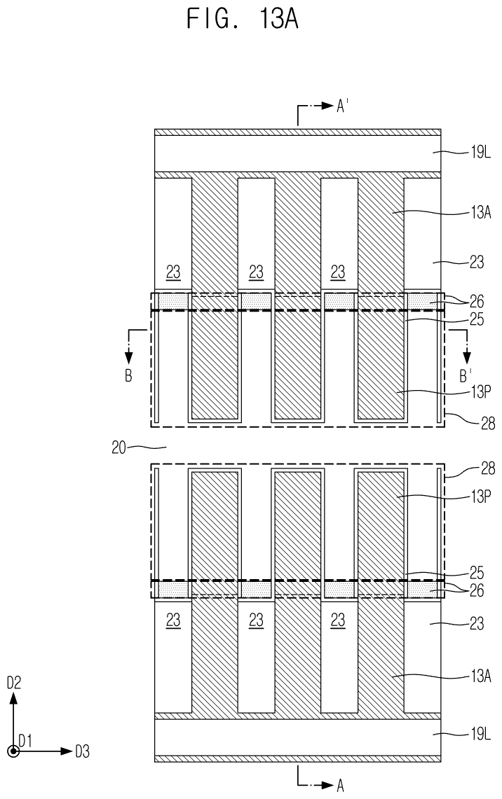

FIG. 9A is a plan view illustrating the structure at the mold layer level for describing the recessing of the sacrificial mold layers 12 and the mold layers 13. FIG. 9B is a cross-sectional view of the structure taken along line A-A′ illustrated in FIG. 9A. FIG. 9C is a cross-sectional view of the structure taken along line B-B′ illustrated in FIG. 9A.

Referring to FIGS. 9A to 9C, among the first linear sacrificial layer 18L and the second linear sacrificial layer 19L, the first linear sacrificial layer 18L may be selectively removed to form a first linear opening 20. A third hard mask layer 17T may be used as an etch barrier to remove the first linear sacrificial layer 18L and form the first linear opening 20. From the perspective of a top view, the first linear opening 20 may be disposed horizontally spaced apart from the second linear sacrificial layer 19L in the second direction D2. The third hard mask layer 17T may include an oxide-based material, a nitride-based material, a carbon-based material, or a combination thereof. For example, the third hard mask layer 17T may include SiO₂, Si₃N₄, amorphous carbon, or a combination thereof.

The first linear opening 20 may have the same size as or may be larger than the first sacrificial linear opening 18 which was described with reference to FIG. 7A. A bottom surface of a bottom portion 20T of the first linear opening 20 may be at the same level as a bottom surface of the first sacrificial linear opening 18. The bottom surface of the first linear opening 20 may be at the same level as a bottom surface of the sacrificial isolation layer 16.

The sacrificial mold layers 12, the first dummy mold layer 12L, the mold layers 13 and the second dummy mold layer 13L may be selectively recessed through the first linear opening 20.

A difference in etch selectivity between the sacrificial mold layers 12 and the mold layers 13 may be used to selectively recess the sacrificial mold layers 12. The sacrificial mold layers 12 may be removed using a wet etch process or a dry etch process. For example, when the sacrificial mold layers 12 include silicon germanium layers, and the mold layers 13 include monocrystalline silicon layers, the silicon germanium layers may be etched using an etchant or etch gas having a selectivity with respect to the monocrystalline silicon layers. A portion of each of the sacrificial mold layers each having an original thickness may remain as indicated by reference numeral “12A”. While the sacrificial mold layers 12 are recessed, the first dummy mold layer 12L may be horizontally recessed.

Subsequently, a portion (a first portion) of each of the mold layers 13 may be recessed to form a narrow sheet 13P and an original body portion 13A. The wet etch process or dry etch process may be used to recess the mold layers 13. An original body portion 13A and a narrow sheet 13P may be formed by the partial recessing of each of the mold layers 13. The original body portion 13A may maintain an original thickness T1, while the narrow sheet 13P may have a thickness T2 less than the original thickness T1. A horizontal length of the original body portion 13A in the second direction D2 may be equal to or different from a horizontal length of the narrow sheet 13P in the second direction D2. A combination of the original body portion 13A and the narrow sheet 13P may be referred to as a “preliminary active layer”. The narrow sheet 13P may be referred to as a “flat plate-shaped sheet” or a “protruding narrow sheet”. While the mold layers 13 are recessed, the second dummy mold layer 13L may be recessed.

A recess process for forming the narrow sheet 13P may be referred to as a “thinning process” or “trimming process” of the mold layer 13. To form the narrow sheet 13P, an upper surface, lower surface and side surface of the mold layer 13 may be recessed. The narrow sheet 13P may be referred to as a “thin-body active layer”. The narrow sheet 13P may include, for example, a monocrystalline silicon layer. The recess process for forming the narrow sheet 13P may use, for example, Hot SC-1 (HSC1). The HSC1 may include, for example, a solution in which ammonium hydroxide (NH₄OH), hydrogen peroxide (H₂O₂) and water (H₂O) are mixed in a ratio of 1:4:20. Using the HSC1, the mold layers 13 may be selectively etched.

The narrow sheets 13P may be formed by the trimming process or the partial recess process for the mold layers 13 as described above. Each of inter-nano sheet recesses 21 may be formed between the narrow sheets 13P that are vertically disposed. Upper and lower surfaces of each of the narrow sheets 13P may each include a flat surface. A boundary portion between the original body portion 13A and the narrow sheet 13P may be vertical or have a curvature. Each of the sacrificial mold layers 12A may be disposed between the original body portions 13A that are vertically stacked.

The inter-nano sheet recesses 21 may include an uppermost inter-nano sheet recess 21U and a lowermost inter-nano sheet recess 21L. A vertical height of the lowermost inter-nano sheet recess 21L may be greater than vertical heights of the uppermost inter-nano sheet recess 21U and inter-nano sheet recesses 21. The lowermost inter-nano sheet recess 21L may provide a space in which a dummy structure is formed, and may be referred to as a “dummy recess,” or “inter-nano dummy recess.”

As described above, the first portions of the mold layers 13 may be trimmed so that a vertical arrangement of the narrow sheets 13P may be formed, and a first portion of the dummy mold SBR may be trimmed so that the dummy recess may be formed.

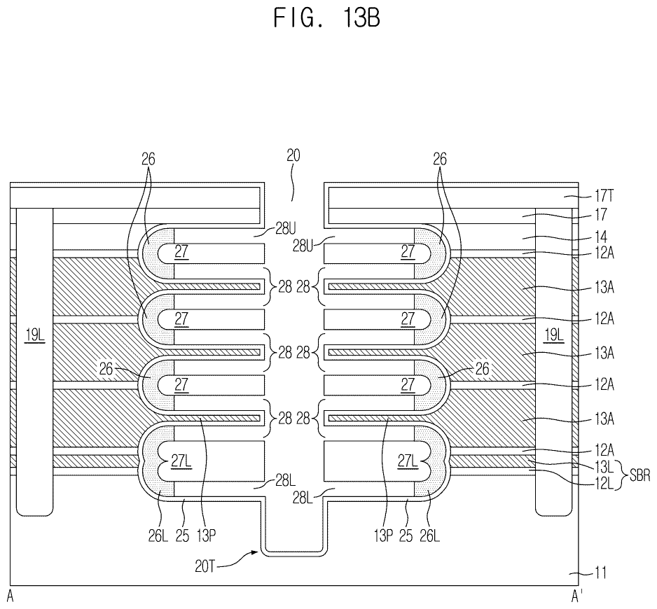

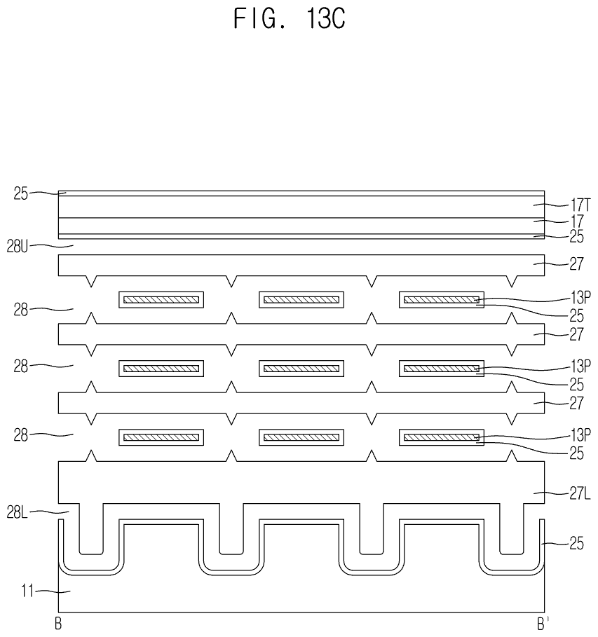

FIG. 10A is a plan view illustrating the structure at a narrow sheet level for describing a method of forming sacrificial isolation layer-level openings 22. FIG. 10B is a cross-sectional view of the structure taken along line A-A′ illustrated in FIG. 10A. FIG. 10C is a cross-sectional view of the structure taken along line B-B′ illustrated in FIG. 10A.

Referring to FIGS. 10A to 10C, the sacrificial isolation layers 16 may be selectively stripped through the inter-nano sheet recesses 21, 21U and 21L. Accordingly, each of the sacrificial isolation layer-level openings 22 may be formed between the original body portions 13A in the third direction D3.

Side surfaces of the sacrificial mold layers 12A, side surfaces of the original body portions 13A and side surfaces of the narrow sheets 13P may be exposed in the third direction D3 by the sacrificial isolation layer-level openings 22.

While the sacrificial isolation layer-level openings 22 are formed, a portion of the first hard mask layer 14 may be recessed and a space of the uppermost inter-nano sheet recess 21U may be expanded. In an embodiment as illustrated in FIG. 10B, the vertical heights of the inter-nano sheet recesses 21 may be equal to the vertical height of the uppermost inter-nano sheet recess 21U. Also, the vertical height of the lowermost inter-nano sheet recess 21L may be greater than the vertical heights of the inter-nano sheet recesses 21. The vertical height may refer to a height in the first direction D1.

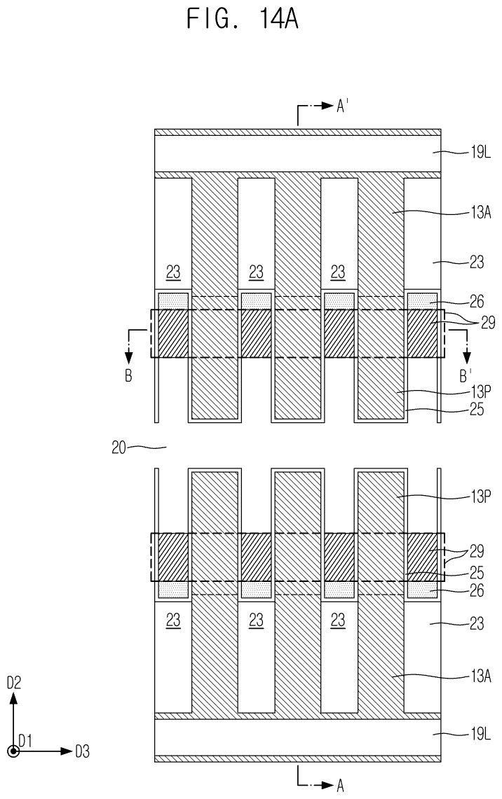

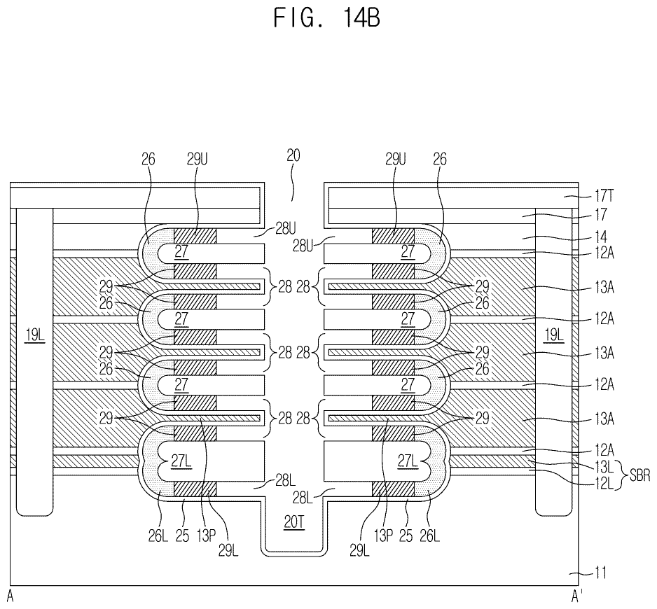

FIG. 11A is a plan view illustrating the structure at the narrow sheet level for describing a method of forming first inter-cell dielectric layers 23. FIG. 11B is a cross-sectional view of the structure taken along line B-B′ illustrated in FIG. 11A.

Referring to FIGS. 11A and 11B, the first inter-cell dielectric layers 23 may be formed in the sacrificial isolation layer-level openings 22. The first inter-cell dielectric layers 23 may each include a dielectric material. The first inter-cell dielectric layers 23 may each include silicon oxide, silicon nitride, silicon carbon oxide, or a combination thereof. Forming the first inter-cell dielectric layers 23 may include forming a dielectric material that fills the sacrificial isolation layer-level openings 22 and performing an etch-back process on the dielectric material.

The first inter-cell dielectric layers 23 may fill portions of the sacrificial isolation layer-level openings 22. The side surfaces of the sacrificial mold layers 12A and the side surfaces of the original body portions 13A may be covered by the first inter-cell dielectric layers 23 in the third direction D3. The first inter-cell dielectric layers 23 may expose the side surfaces of the narrow sheets 13P. The other portions of the sacrificial isolation layer-level openings 22, i.e., non-gap-filled portions 22A, may expose the side surfaces of the narrow sheets 13P.

After the first inter-cell dielectric layers 23 are formed, a nano sheet all-open recess 24A that opens all of the narrow sheets 13P may be formed. The nano sheet all-open recess 24A may refer to a combination of the inter-nano sheet recesses 21 and the non-gap-filled portions 22A of the sacrificial isolation layer-level openings 22. The nano sheet all-open recess 24A may include a plurality of surrounding recesses 24. The surrounding recesses 24 may expose all of the narrow sheets 13P at the same horizontal level in the third direction D3. For example, any one of the surrounding recesses 24 extending in the third direction D3 may surround all surfaces of the narrow sheets 13P at the same horizontal level.

Each of the surrounding recesses 24 may include a plurality of initial gaps 24G, and the initial gaps 24G may be defined between the narrow sheets 13P in the third direction D3. The initial gaps 24G may be portions of the non-gap-filled portions 22A.

FIG. 12A is a plan view illustrating the structure at the narrow sheet level for describing a method of forming a first spacer layer 26A and a second inter-cell dielectric layer 27A. FIG. 12B is a cross-sectional view of the structure taken along line A-A′ illustrated in FIG. 12A. FIG. 12C is a cross-sectional view of the structure taken along line B-B′ illustrated in FIG. 12A.

Referring to FIGS. 12A to 12C, a nano sheet dielectric layer 25 may be formed on exposed portions of the narrow sheets 13P. The nano sheet dielectric layer 25 may be referred to as a “gate dielectric layer,” or “nano sheet gate dielectric layer.”

The nano sheet dielectric layer 25 may be formed by oxidizing the surfaces of the narrow sheets 13P. In some embodiments, the nano sheet dielectric layer 25 may be formed by deposition and oxidation processes of silicon oxide. The nano sheet dielectric layer 25 may include silicon oxide, silicon nitride, metal oxide, metal oxynitride, metal silicate, a high-k material, a ferroelectric material, an anti-ferroelectric material, or a combination thereof. The nano sheet dielectric layer 25 may include silicon dioxide (SiO₂), silicon nitride (Si₃N₄), hafnium dioxide (HfO₂), aluminum oxide (Al₂O₃), zirconium dioxide (ZrO₂), aluminum oxynitride (AlON), hafnium oxynitride (HfON), hafnium silicate (HfSiO), hafnium silicon oxynitride (HfSiON), or a combination thereof. The nano sheet dielectric layer 25 may be formed on all surfaces of the narrow sheets 13P.

The first spacer layer 26A may be formed on the nano sheet dielectric layer 25. The first spacer layer 26A may include, for example, silicon nitride. The first spacer layer 26A may surround and cover the narrow sheets 13P on the nano sheet dielectric layer 25. The first spacer layer 26A may be thicker than the nano sheet dielectric layer 25.

The second inter-cell dielectric layer 27A may be formed on the first spacer layer 26A. The second inter-cell dielectric layer 27A may include, for example, silicon oxide.

The nano sheet dielectric layer 25 and the first spacer layer 26A may also be formed on the surface of the substrate 11.

As described above, each of the first spacer layer 26A may be disposed between the narrow sheets 13P in the third direction D3. The second inter-cell dielectric layer 27A may be disposed between the first spacer layers 26A in the first direction D1.

FIG. 13A is a plan view illustrating the structure at the narrow sheet level for describing a method of forming first spacers 26. FIG. 13B is a cross-sectional view of the structure taken along line A-A′ illustrated in FIG. 13A. FIG. 13C is a cross-sectional view of the structure taken along line B-B′ illustrated in FIG. 13A.

Referring to FIGS. 13A to 13C, the second inter-cell dielectric layer 27A may be cut through the first linear opening 20. Subsequently, the first spacer layer 26A may be selectively recessed and the remaining first spacer layers may become the first spacers 26, and the second inter-cell dielectric layers may remain as indicated by reference numeral “27”. The first spacers 26 may correspond to the first spacer SP1 as described above with reference to FIGS. 4A and 4B.

As the first spacers 26 are formed, linear surrounding recesses 28 surrounding the narrow sheets 13p may be formed on the nano sheet dielectric layer 25. Each of the second inter-cell dielectric layers 27 may be disposed between the linear surrounding recesses 28 that are vertically disposed. An upper-level dummy horizontal recess 28U may be formed on an uppermost second inter-cell dielectric layer 27. Also, a lower-level dummy horizontal recess 28L may be formed below a lowermost second inter-cell dielectric layer 27L. The upper-level and the lower-level dummy horizontal recesses 28U and 28L may each have a non-surrounding shape and have a flat shape. The lowermost second inter-cell dielectric layer 27L may be a dummy dielectric layer 27L. A lowermost first spacer may be a dummy spacer 26L.

The dummy spacer 26L may be disposed on a side surface of the dummy dielectric layer 27L. A vertical height of the dummy spacer 26L may be greater than vertical heights of the first spacers 26. A vertical height of the dummy dielectric layer 27L may be greater than vertical heights of the second inter-cell dielectric layers 27. In some embodiments, the first spacers 26 and the dummy spacer 26L may have an integral structure (also referred to as a continuous structure) in the first direction D1. The dummy dielectric layer 27L may correspond to the dummy dielectric layers DIL illustrated in FIG. 4B, and the dummy spacer 26L may correspond to the dummy spacers DSP illustrated in FIG. 4B.

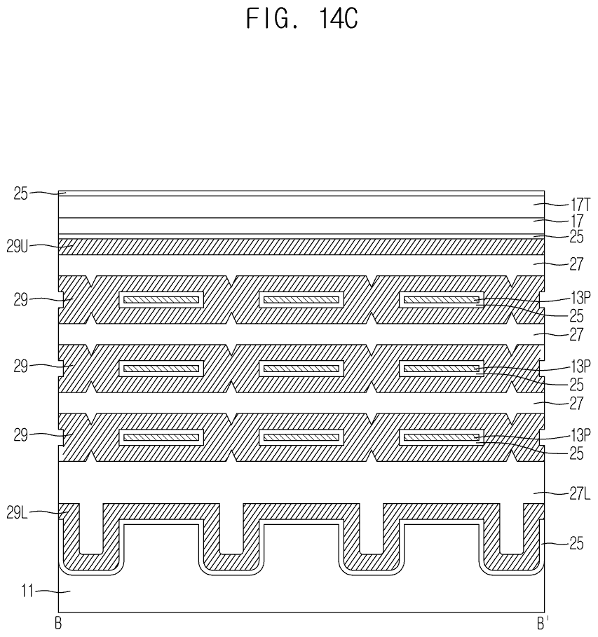

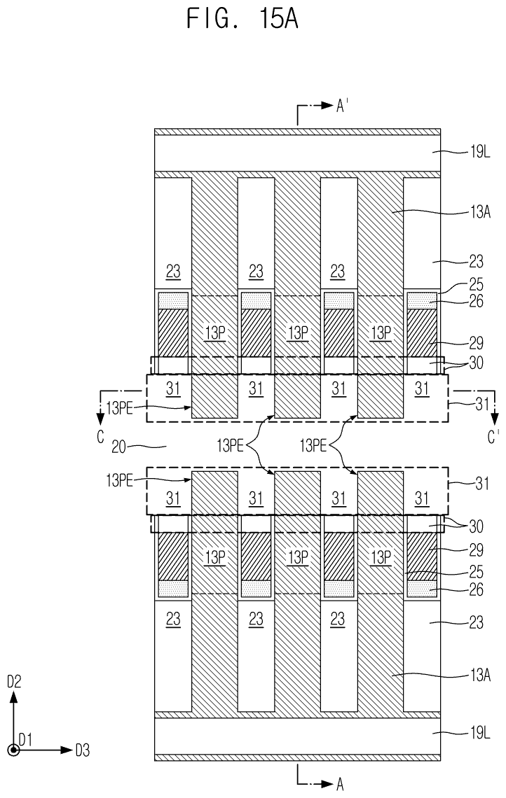

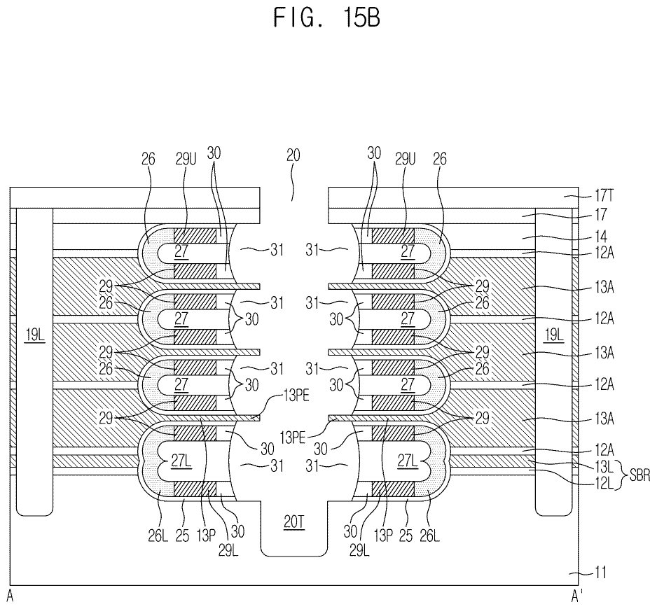

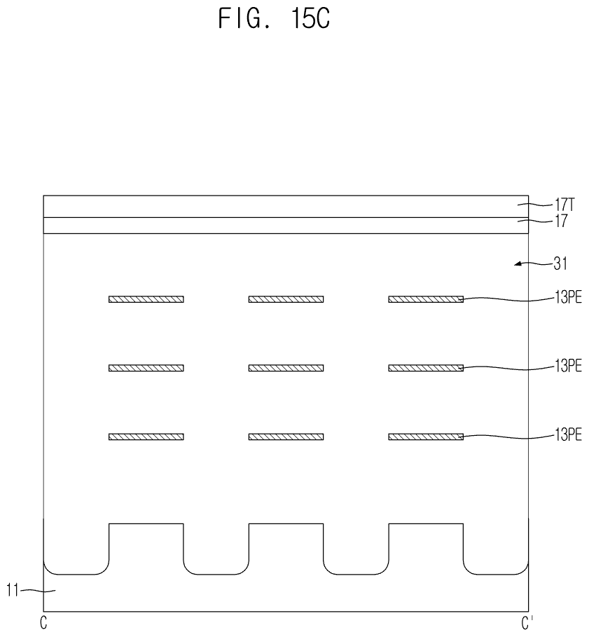

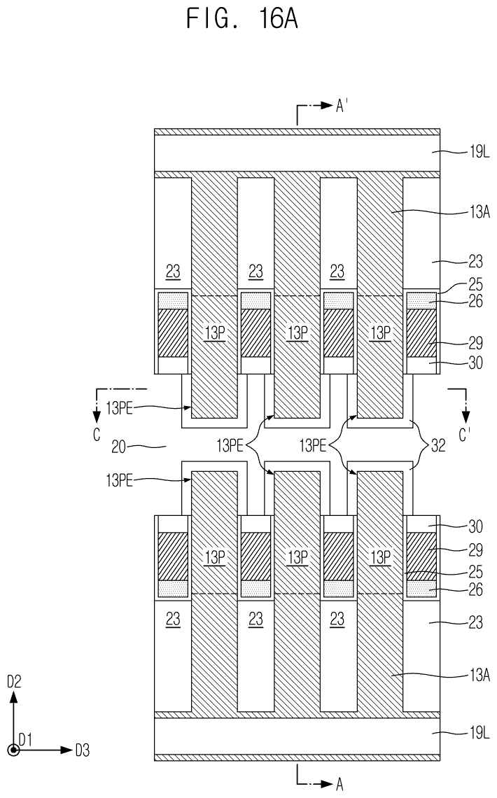

FIG. 14A is a plan view illustrating the structure at the narrow sheet level for describing a method of forming horizontal conductive lines 29. FIG. 14B is a cross-sectional view of the structure taken along line A-A′ illustrated in FIG. 14A. FIG. 14C is a cross-sectional view of the structure taken along line B-B′ illustrated in FIG. 14A.

Referring to FIGS. 14A to 14C, the horizontal conductive lines 29 may be formed to horizontally and partially fill the linear surrounding recesses 28. The horizontal conductive lines 29 may horizontally extend in the third direction D3. The horizontal conductive lines 29 may correspond to the first conductive lines WL as described above with reference to FIGS. 4A to 4C.

Forming the horizontal conductive lines 29 may include depositing a conductive material that fills the linear surrounding recesses 28 on the nano sheet dielectric layer 25 and performing a horizontal etch-back process on the conductive material. Each of the horizontal conductive lines 29 may simultaneously surround a portion of the narrow sheets 13P at the same level. The horizontal conductive lines 29 may each include a metal-based material, a semiconductive material, or a combination thereof. The horizontal conductive lines 29 may each include molybdenum, molybdenum nitride, ruthenium, titanium nitride, tungsten, polysilicon, or a combination thereof. For example, the horizontal conductive lines 29 may each include a titanium nitride and tungsten (TiN/W) stack in which titanium nitride and tungsten are sequentially stacked. The horizontal conductive lines 29 may each include an N-type work function material or a P-type work function material. The N-type work function material may have a low work function of approximately 4.5 eV or less, and the P-type work function material may have a high work function of approximately 4.5 eV or greater. Each of the second inter-cell dielectric layers 27 may be disposed between a plurality of horizontal conductive lines 29 in the first direction D1. The horizontal conductive lines 29 surrounding the narrow sheets 13P may be referred to as “gate-all-around (GAA) electrodes”. The narrow sheets 13P may be referred to as “nano sheet channels”, “nano wires” or “nano wire channels”.

A lower-level dummy conductive line 29L may be formed on the surface of the substrate 11. An upper-level dummy conductive line 29U may be formed over an uppermost horizontal conductive line 29. The lower-level and the upper-level dummy conductive lines 29L and 29U may each have a non-surrounding shape. The dummy dielectric layer 27L may be disposed between a lowermost horizontal conductive line 29 and the lower-level dummy conductive line 29L. A vertical gap between the lowermost horizontal conductive line 29 and the lower-level dummy conductive line 29L may be greater than a vertical gap between the horizontal conductive lines 29 by the dummy dielectric layer 27L.

The lower-level dummy conductive line 29L may correspond to the dummy conductive line WLL as described above with reference to FIGS. 4B and 4C.

As described above, the horizontal conductive lines 29 that are horizontally oriented may be formed to partially surround the respective narrow sheets 13P in the vertical arrangement. The dummy spacer 26L, the dummy dielectric layer 27L and the lower-level dummy conductive line 29L may be formed in the dummy recess.

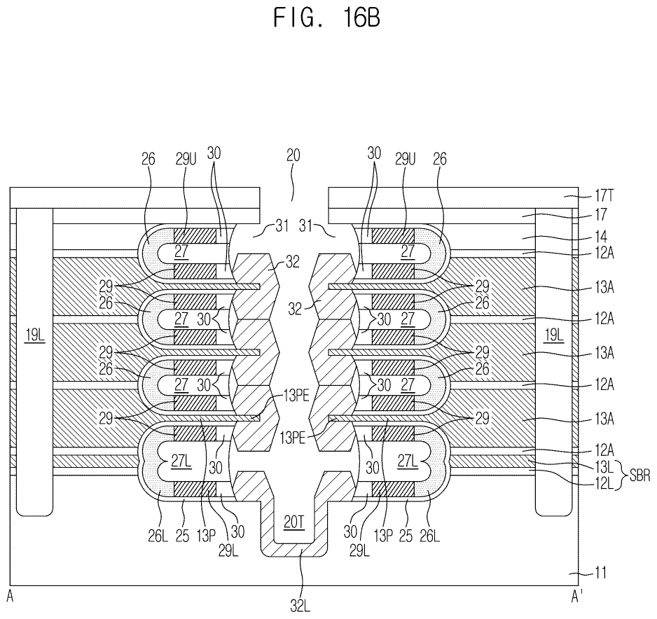

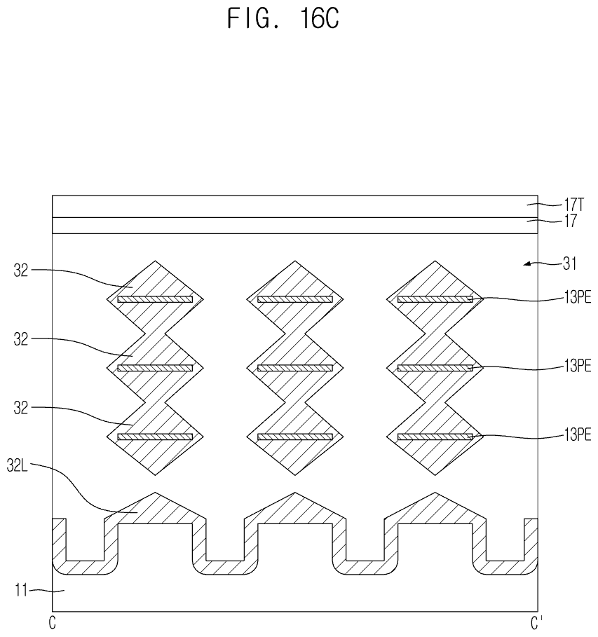

FIG. 15A is a plan view illustrating the structure at the narrow sheet level for describing a method of forming second spacers 30. FIG. 15B is a cross-sectional view of the structure taken along line A-A′ illustrated in FIG. 15A. FIG. 15C is a cross-sectional view of the structure taken along line C-C′ illustrated in FIG. 15A.

Referring to FIGS. 15A to 15C, each of the second spacers 30 may be formed on one side of each of the horizontal conductive lines 29. The second spacer 30 may include silicon oxide, silicon nitride, silicon carbon oxide, an embedded air gap, or a combination thereof. A process for forming the second spacer 30 may include first depositing a spacer material and then performing an etch-back of the spacer material. In an embodiment, the second spacer 30 may include a stack of a silicon oxide liner and a silicon nitride liner.

The second spacer 30 may be disposed on one side of each of the horizontal conductive lines 29 and extend in the third direction D3. The second spacer 30 may surround portions of the narrow sheets 13P at the same horizontal level, which are arranged in the third direction D3.

The second spacer 30 may correspond to the second spacer SP2 as described above with reference to FIGS. 4A and 4B.

After the second spacers 30 are formed, the nano sheet dielectric layer 25, the second inter-cell dielectric layers 27 and the dummy dielectric layer 27L may be cut to expose one side of each of the narrow sheets 13P and form inter-narrow sheet recesses 31 which expose edge portions 13PE of the narrow sheets 13P.

Through a series of processes as described above, the horizontal conductive lines 29, the narrow sheets 13P, the second inter-cell dielectric layers 27, the first spacer 26 and the second spacer 30 may be formed in a first region of the mold stack SB. In addition, the dummy structure may be formed in a first region of the dummy mold SBR and over the substrate 11. The dummy structure may include the lower-level dummy horizontal electrode 29L, the dummy dielectric layer 27L, and the dummy spacer 26L. The lowermost horizontal conductive line 29 and the substrate 11 may be spaced apart from each other by the dummy structure.

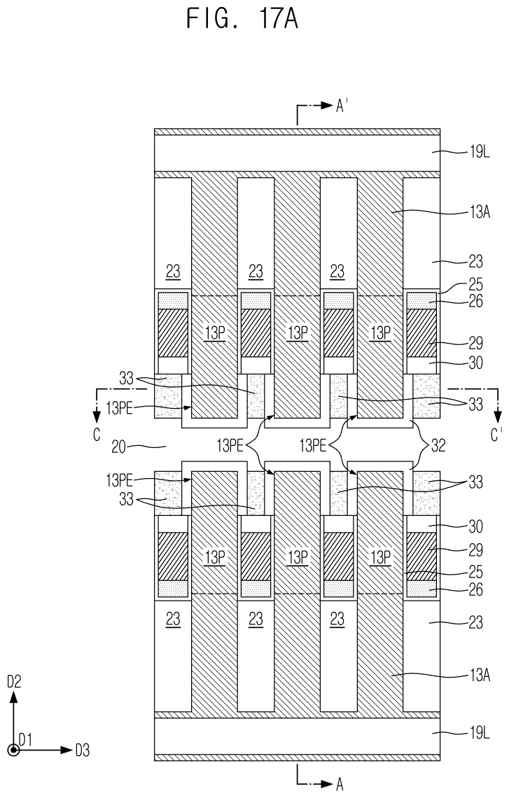

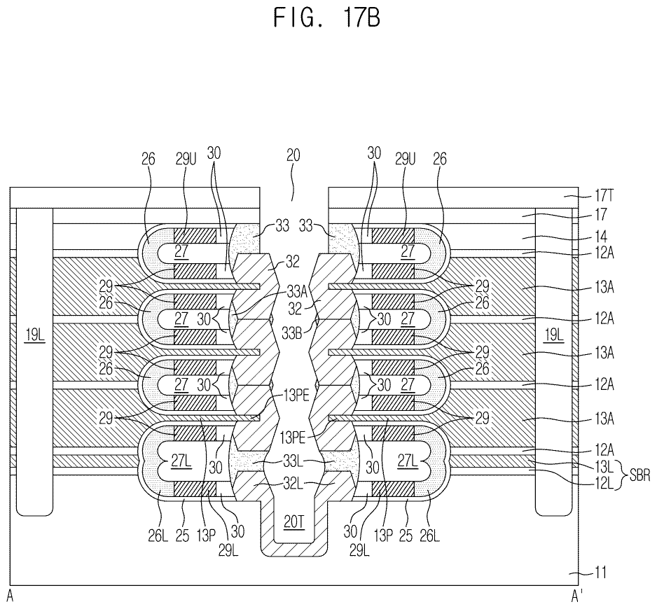

FIG. 16A is a plan view illustrating the structure at the narrow sheet level for describing a method of forming sacrificial growth layers 32. FIG. 16B is a cross-sectional view of the structure taken along line A-A′ illustrated in FIG. 16A. FIG. 16C is a cross-sectional view of the structure taken along line C-C′ illustrated in FIG. 16A.

Referring to FIGS. 16A to 16C, the sacrificial growth layers 32 may be formed on the edge portions 13PE of the narrow sheets 13P through selective epitaxial growth (SEG). The sacrificial growth layers 32 may include semiconductor materials. In an embodiment, the sacrificial growth layers 32 may be epitaxial layers of silicon germanium layers. Referring back to FIG. 16A, the sacrificial growth layers 32 may not contact each other in the third direction D3. Referring back to FIG. 16B, the sacrificial growth layers 32 may contact each other in the first direction D1. A gap may be defined between each of the sacrificial growth layers 32 and each of the second inter-cell dielectric layers 27. The inter-narrow sheet recesses 31 may be partially filled with the sacrificial growth layers 32. The sacrificial growth layers 32 may include a plurality of facets.

While the sacrificial growth layers 32 are formed on the edge portions 13PE of the narrow sheets 13P, bottom sacrificial growth layers 32L may also be formed on the surface of the substrate 11. The bottom sacrificial growth layers 32L may be formed on the bottom portion 20T of the first linear opening 20. Referring back to FIG. 16B, the bottom sacrificial growth layers 32L and lowermost sacrificial growth layers 32 may not contact each other in the first direction D1.

As described above, the sacrificial growth layers 32 may be formed on one side of the narrow sheets 13P in the vertical arrangement.

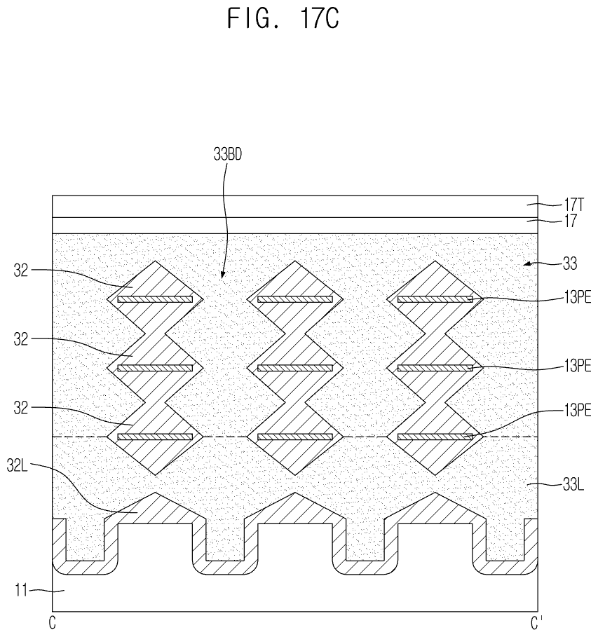

FIG. 17A is a plan view illustrating the structure at the narrow sheet level for describing a method of forming a supporter structure 33. FIG. 17B is a cross-sectional view of the structure taken along line A-A′ illustrated in FIG. 17A. FIG. 17C is a cross-sectional view of the structure taken along line C-C′ illustrated in FIG. 17A.

Referring to FIGS. 17A to 17C, the supporter structure 33 may be formed by filling the gaps between the sacrificial growth layers 32 with a dielectric material. The forming process for the supporter 33 may include first deposition of the dielectric material followed by an etch-back of the dielectric material performed on the deposited dielectric material to form the supporter structure 33. Referring back to FIG. 17A, certain portions of the supporter structure 33 may be disposed between the sacrificial growth layers 32 along the third direction D3. Referring back to FIG. 17B, portions of the supporter structure 33 may be disposed between the sacrificial growth layers 32 and the second inter-cell dielectric layers 27. In addition, the outer sides of the boundaries of the sacrificial growth layers 32 in the first direction D1 may contact portions of the supporter structure 33. The supporter structure 33 may be referred to as a “third spacer”. The supporter structure 33 may include a low-k material, silicon oxide, silicon carbon oxide, silicon nitride, an air gap, or a combination thereof.

The supporter structure 33 may support the sacrificial growth layers 32.

Referring back to FIG. 17B, a bottom isolation portion 33L may be disposed between the bottom sacrificial growth layers 32L and the lowermost sacrificial growth layers 32 in the first direction D1. The bottom isolation portion 33L, which is a portion of the supporter structure 33, may be simultaneously formed while the supporter structure 33 is formed. The bottom isolation portion 33L may fill the dummy recess.

The supporter structure 33 may correspond to the supporter structure BLS described above with reference to FIGS. 2A, 3A, 3B, 4A and 4B. The supporter structure 33 may be vertically oriented from the bottom isolation portion 33L. The supporter structure 33 may have the same structure as the supporter structure BLS described above with reference to FIG. 3A. For example, the supporter structure 33 may include support bodies 33BD, which correspond to reference symbol “SBD” in FIG. 3A, outer support spacers 33B, which correspond to reference symbol “BR1” in FIG. 3A, and inner support spacers 33A, which correspond to reference symbol “BR2” in FIG. 3A. Outer portions of the sacrificial growth layers 32 may contact the outer support spacers 33B of the supporter structure 33, and inner portions of the sacrificial growth layers 32 may contact the inner support spacers 33A of the supporter structure 33. The outer support spacers 33B of the supporter structure 33 may partially expose surfaces of the outer portions of the sacrificial growth layers 32. The inner support spacers 33A of the supporter structure 33 may partially expose surfaces of the inner portions of the sacrificial growth layers 32.

The bottom isolation portion 33L may have an integral (or continuous) structure made from a dielectric material and may be extending in the third direction D3. The bottom isolation portion 33L and the supporter structure 33 may be composed of the same material. A combination of the bottom isolation portion 33L and the supporter structure 33 may form an integral structure (or continuous structure) without a physical interface.

The dummy dielectric layers 27L may be formed horizontally adjacent to the bottom isolation portion 33L. The vertical heights of the dummy dielectric layers 27L may be greater than the vertical heights of the second inter-cell dielectric layers 27. The dummy spacers 26L may be formed on one side of the dummy dielectric layers 27L. The lower-level dummy conductive lines 29L may contact lower surfaces of the dummy dielectric layers 27L.

The lowermost horizontal conductive line 29 and the lower-level dummy conductive lines 29L may be sufficiently spaced apart from each other by at least the thickness of the dummy dielectric layers 27L. In addition, the lowermost horizontal conductive line 29 and the substrate 11 may be sufficiently spaced apart from each other by the bottom isolation portion 33L.

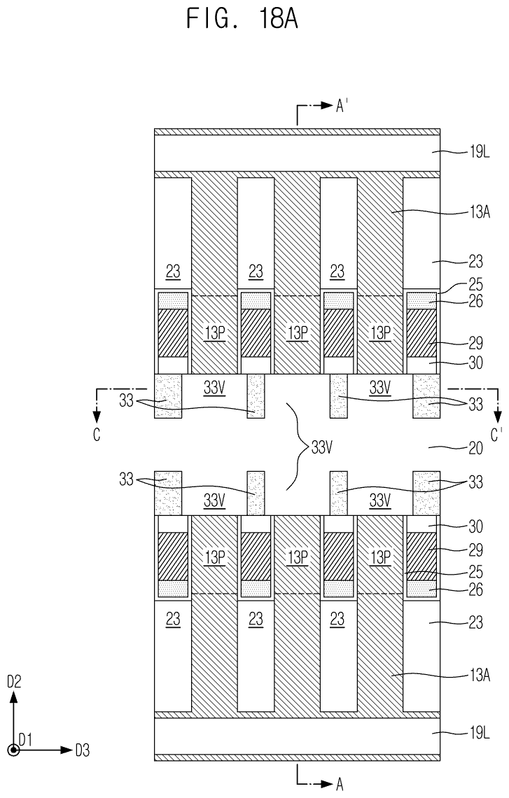

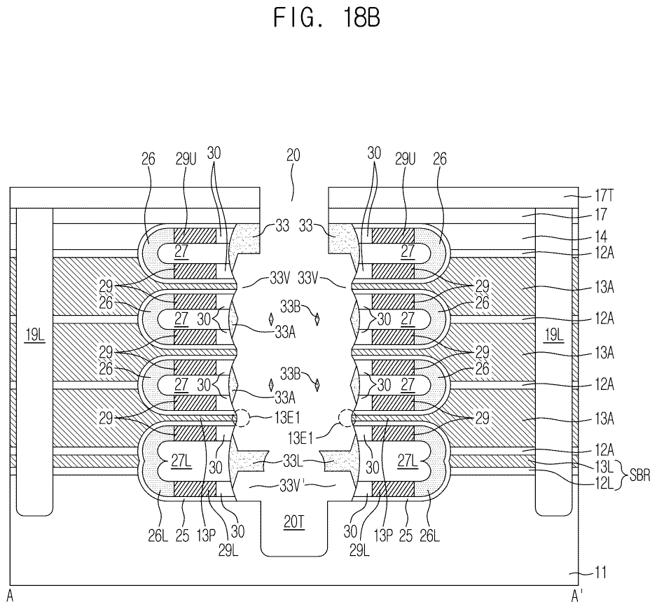

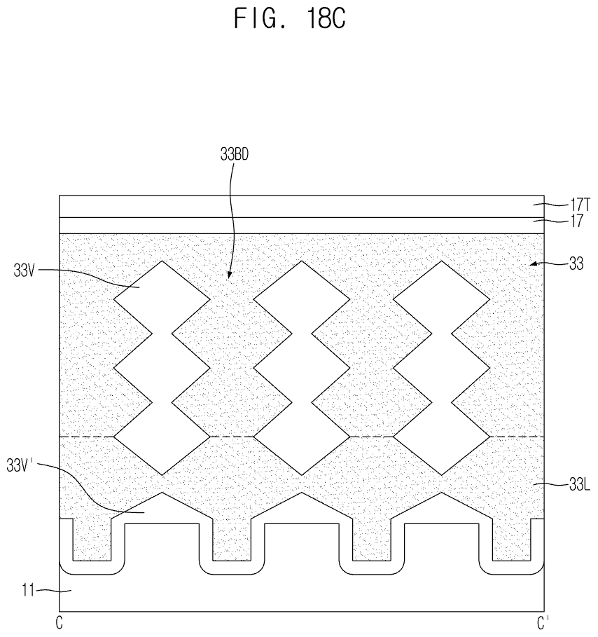

FIG. 18A is a plan view illustrating the structure at the narrow sheet level for describing a method of forming vertical openings 33V. FIG. 18B is a cross-sectional view of the structure taken along line A-A′ illustrated in FIG. 18A. FIG. 18C is a cross-sectional view of the structure taken along line C-C′ illustrated in FIG. 18A.

Referring to FIGS. 18A to 18C, the sacrificial growth layers 32 may be removed, and a plurality of vertical openings 33V may be formed in the supporter structure 33. The vertical openings 33V that are horizontally adjacent to each other in the second direction D2 may be spaced apart from each other. The vertical openings 33V may correspond to the supporter openings SVL illustrated in FIGS. 3A and 3B. While the sacrificial growth layers 32 are removed, the bottom sacrificial growth layers 32L may be removed, and accordingly, a bottom dummy recess 33V′ may be formed between the bottom isolation portion 33L and the substrate 11. The bottom dummy recess 33V′ may extend in the third direction D3.

After the vertical openings 33V are formed, the edge portions of the narrow sheets 13P may be cut. Accordingly, the narrow sheets 13P may have shortened cut portions 13E1. The cut portions 13E1 may each have a non-protruding shape.

As described above, the vertical openings 33V of the supporter structure 33 may be formed through the growth and removal of the sacrificial growth layers 32. In some embodiments, the vertical openings 33V may be referred to as “supporter openings”, “vertically-oriented openings”, “vertical damascene patterns”, or “vertically-oriented inner portions”. The supporter structure 33 may have an integral structure having a plurality of vertically-oriented openings.

The vertical openings 33V may simultaneously expose the cut portions 13E1 of the narrow sheets 13P that are vertically disposed in the first direction D1.

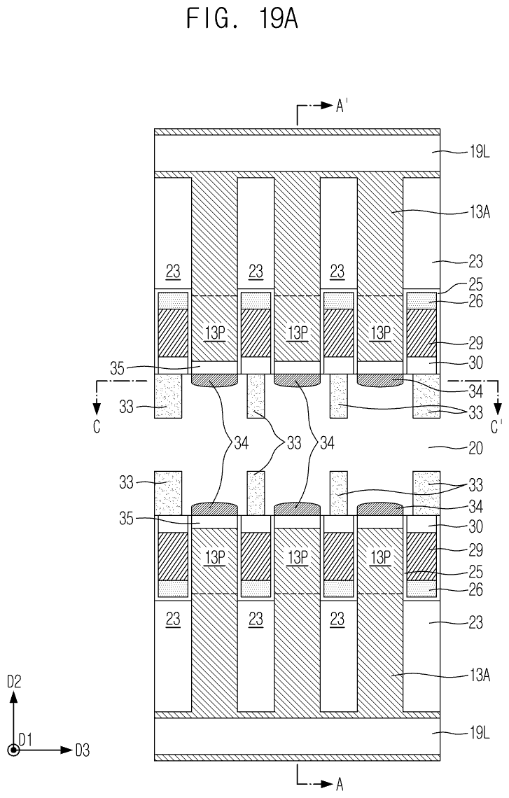

FIG. 19A is a plan view illustrating the structure at the narrow sheet level for describing a method of forming first contact nodes 34. FIG. 19B is a cross-sectional view of the structure taken along line A-A′ illustrated in FIG. 19A. FIG. 19C is a cross-sectional view of the structure taken along line C-C′ illustrated in FIG. 19A.

Referring to FIGS. 19A to 19C, the first contact nodes 34 may be formed on the cut portions 13E1 of the narrow sheets 13P. Forming the first contact nodes 34 may include selective epitaxial growth (SEG). For example, a semiconductive material may be grown from the cut portions 13E1 of the narrow sheets 13P through the SEG. The first contact nodes 34 may each include SEG Si. Because the narrow sheets 13P include monocrystalline silicon, a silicon layer may be epitaxially grown along crystal surfaces of side surfaces of the narrow sheets 13P.

The first contact nodes 34 may include a dopant. When a silicon layer is grown using the SEG, the dopants may be doped in situ. Accordingly, the first contact nodes 34 may be doped epitaxial layers. The first contact nodes 34 may each include an N-type dopant. The N-type dopant may include phosphorus, arsenic, antimony, or a combination thereof. The first contact nodes 34 may each include a phosphorus-doped silicon epitaxial layer formed by the SEG, i.e., doped SEG SiP.

First doped regions 35 may be formed in one side of the narrow sheets 13P. A heat treatment process may be performed to form the first doped regions 35 for diffusing the dopants from the first contact nodes 34. In another a method of forming the first doped regions 35, a gas phase doping method may be applied.

While the first contact nodes 34 are formed, dummy contact nodes 34L may be formed on the surface of the substrate 11. While the first doped regions 35 are formed, a dummy doped region 35L may be formed in the surface of the substrate 11. The first contact nodes 34 and the dummy contact nodes 34L may be made of the same material. That is, the dummy contact nodes 34L may each include a doped epitaxial layer formed by the SEG. The dummy doped region 35L may include impurities diffused from the dummy contact nodes 34L.

The dummy contact nodes 34L may correspond to the dummy contact node DC1 illustrated in FIGS. 4A and 4B, and the first doped regions 35 may correspond to the first doped regions SR illustrated in FIGS. 4A and 4B. The dummy doped region 35L may correspond to the dummy doped region DC2 illustrated in FIGS. 4A and 4B.

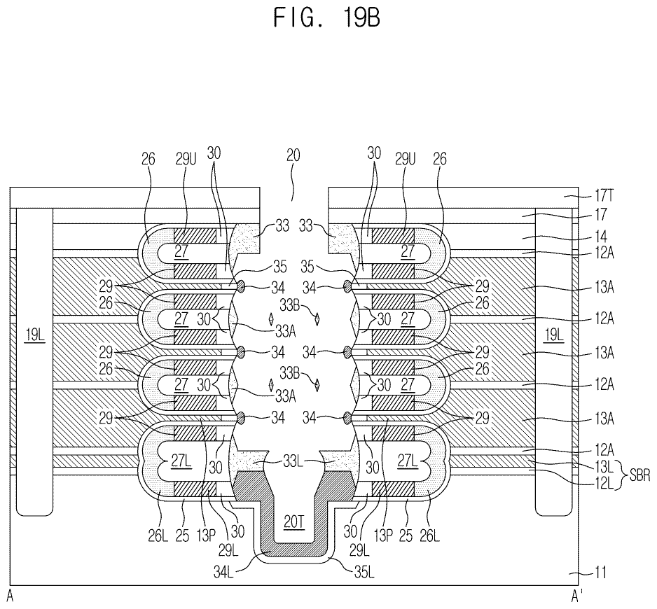

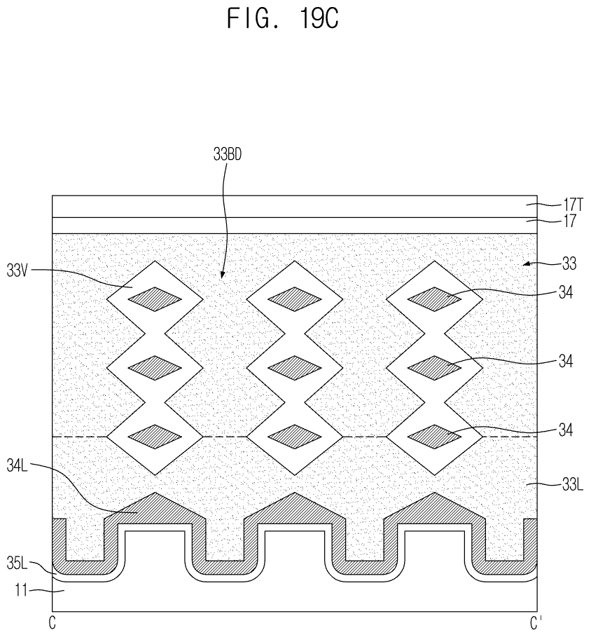

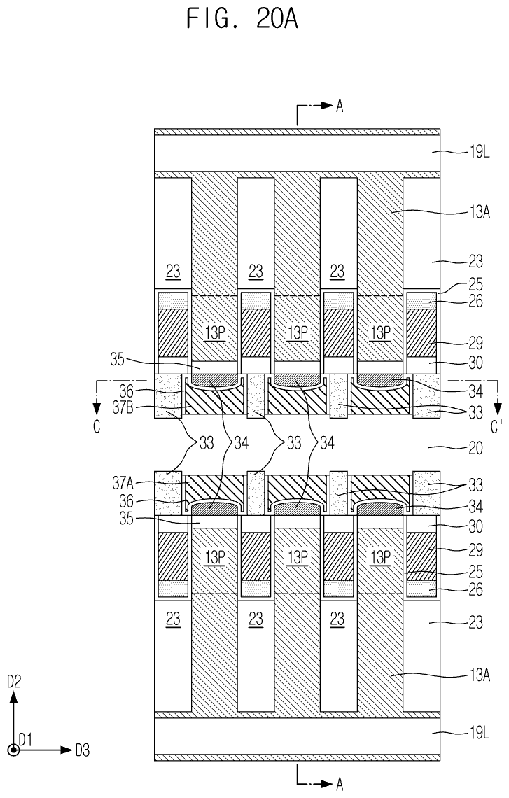

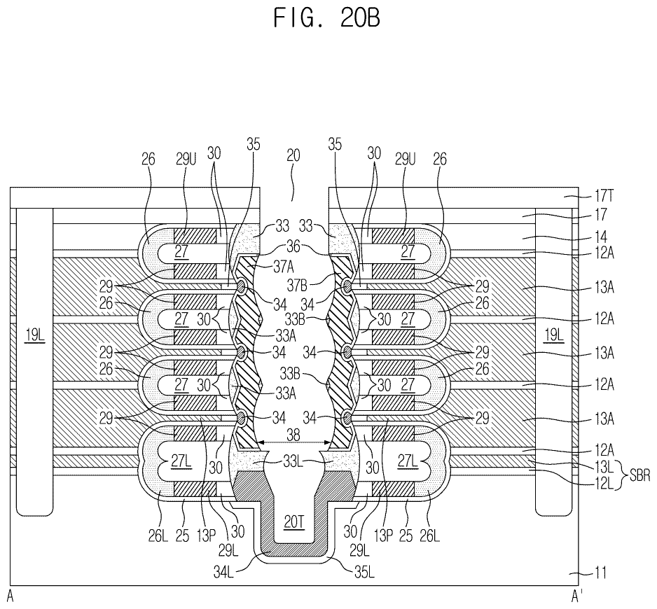

FIG. 20A is a plan view illustrating the structure at the narrow sheet level for describing a method of forming first and second vertical conductive lines 37A and 37B. FIG. 20B is a cross-sectional view of the structure taken along line A-A′ illustrated in FIG. 20A. FIG. 20C is a cross-sectional view of the structure taken along line C-C′ illustrated in FIG. 20A.

Referring to FIGS. 20A to 20C, barrier layers 36 may be formed on the first contact nodes 34. The barrier layers 36 may each include metal nitride, such as titanium nitride. Subsequently, an ohmic contact layer, such as metal silicide, may be further formed between the barrier layers 36 and the first contact nodes 34. The barrier layers 36 may cover the first contact nodes 34.

The first contact nodes 34 may correspond to the first contact nodes BLC illustrated in FIGS. 4A and 4B, and the barrier layers 36 may correspond to the barrier layers BLM illustrated in FIGS. 4A and 4B.

The first and second vertical conductive lines 37A and 37B may be formed on the barrier layers 36 and may cover the barrier layers 36. The first and second vertical conductive lines 37A and 37B may be coupled in common to the first contact nodes 34 through the barrier layers 36. Accordingly, the first and second vertical conductive lines 37A and 37B may be coupled in common to the narrow sheets 13P arranged in the first direction D1. The first and second vertical conductive lines 37A and 37B may each include a metal-based material. For example, the first and second vertical conductive lines 37A and 37B may each include titanium nitride, tungsten, or a combination thereof. The first and second vertical conductive lines 37A and 37B may correspond to the first and second vertical conductive lines BLA and BLB illustrated in FIGS. 4A and 4B.

Forming the first and second vertical conductive lines 37A and 37B may include depositing a vertical conductive line material and performing an etch-back process on the vertical conductive line material. In this way, the first and second vertical conductive lines 37A and 37B may be formed to be self-aligned with the supporter structure 33 through a blanket etch-back process without a mask.

Bottom portions of the first vertical conductive lines 37A and bottom portions of the second vertical conductive lines 37B may be discontinuous to each other (refer to reference numeral “38”). The first and second vertical conductive lines 37A and 37B may be disposed in the vertical openings (reference numeral “33V” in FIG. 18A) that horizontally extend from the first linear opening 20. The first and second vertical conductive lines 37A and 37B may vertically extend in the first direction D1. Outer and inner surfaces of the first and second vertical conductive lines 37A and 37B may have non-linear profiles.

The first and second vertical conductive lines 37A and 37B may correspond to the second conductive line BL described above with reference to FIG. 3C. That is, the first and second vertical conductive lines 37A and 37B may each include an outer portion S1, an inner portion S2, and non-linear side walls NLS as described above with reference to FIG. 3C. The non-linear side walls NLS of the first and second vertical conductive lines 37A and 37B may include a plurality of angled corners AR. Exposed surfaces of the inner portions S2 of the first and second vertical conductive lines 37A and 37B may be electrically coupled to the first doped regions 35 through the barrier layers 36 and the first contact nodes 34.

The first and second vertical conductive lines 37A and 37B may surround the first contact nodes 34 arranged in the first direction D1. The barrier layer 36 may be formed on the outer walls of the first and the second vertical conductive lines 37A and 37B while also surrounding the first contact nodes 34.

The first and second vertical conductive lines 37A and 37B may be supported by the supporter structure 33. The first and second vertical conductive lines 37A and 37B may be embedded in the supporter structure 33, and bottom portions of the first and second vertical conductive lines 37A and 37B may be isolated from each other by the bottom isolation portion 33L. The bottom isolation portion 33L may prevent bridging of the first vertical conductive lines 37A and second vertical conductive lines 37B that are horizontally adjacent to each other. In addition, the first and second vertical conductive lines 37A and 37B may be sufficiently spaced apart from the substrate 11 by the bottom isolation portion 33L and the dummy dielectric layer 27L. The bottom isolation portion 33L may serve as a blocking layer that prevents the bottom portions of the first and second vertical conductive lines 37A and 37B and the substrate 11 from coming into contact.

Referring back to FIG. 20A, portions of the supporter structure 33 may be disposed between the first and second vertical conductive lines 37A and 37B in the third direction D3. The first and second vertical conductive lines 37A and 37B may be formed to be self-aligned with the supporter structure 33. Referring back to FIG. 20B, the first and second vertical conductive lines 37A and 37B may vertically extend in the first direction D1 and be disposed in the vertical openings 33V of the supporter structure 33. The bottom isolation portion 33L may be disposed between the bottom portions of the first and second vertical conductive lines 37A and 37B and the dummy contact nodes 34L. The bottom portions of the first and second vertical conductive lines 37A and 37B and the substrate 11 may be prevented from coming into contact by the bottom isolation portion 33L. The first and second vertical conductive lines 37A and 37B which are formed to be self-aligned with the supporter structure 33 may be referred to as a self-aligned bit line (SABL) structure.

As described above, the supporter structure 33 may include the vertical openings 33V, and the first and second vertical conductive lines 37A and 37B may be formed in the vertical openings 33V of the supporter structure 33. The forming of the vertical openings 33V of the supporter structure 33 may include the growth and removal of the sacrificial growth layers 32.

Because the first and second vertical conductive lines 37A and 37B are formed to be self-aligned using the supporter structure 33 and the bottom isolation portion 33L, the bottom portions of the first and second vertical conductive lines 37A and 37B may be easily isolated.

In a comparative example, a substrate having a silicon-on-insulator (SOI) structure may be used to isolate the first and second vertical conductive lines 37A and 37B from the substrate 11. However, in the comparative example, wafer bonding is required to form an SOI substrate, and two wafers, i.e., a wafer for a mold stack and a wafer for the SOI substrate, are required. Consequently, the cost of the comparative example structure increases inevitably.

In an embodiment, because the SOI substrate and wafer bonding are not required, it is possible to suppress an increase in cost and easily isolate the bottom portions of the first and second vertical conductive lines 37A and 37B. An isolation structure of the bottom portions of the first and second vertical conductive lines 37A and 37B according to the embodiment may be referred to as an “SOI-free structure”.

Subsequently, wide sheets, second contact nodes and data storage elements may be formed in a second region of the mold stack SB. In addition, a second region of the dummy mold SBR may be removed.

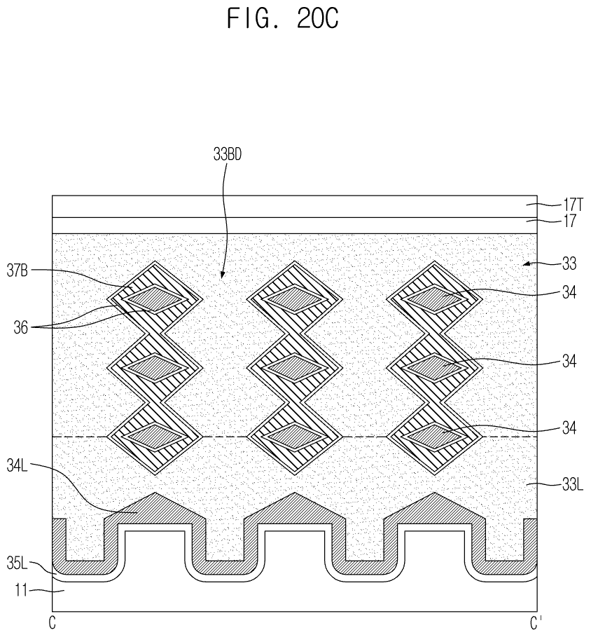

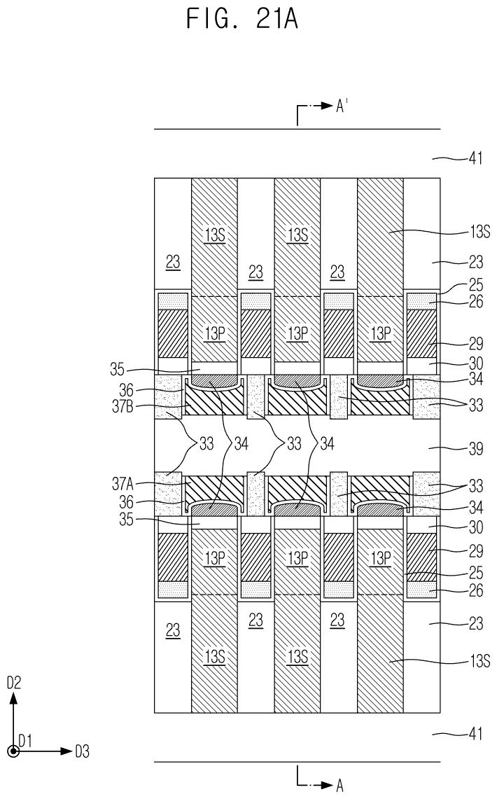

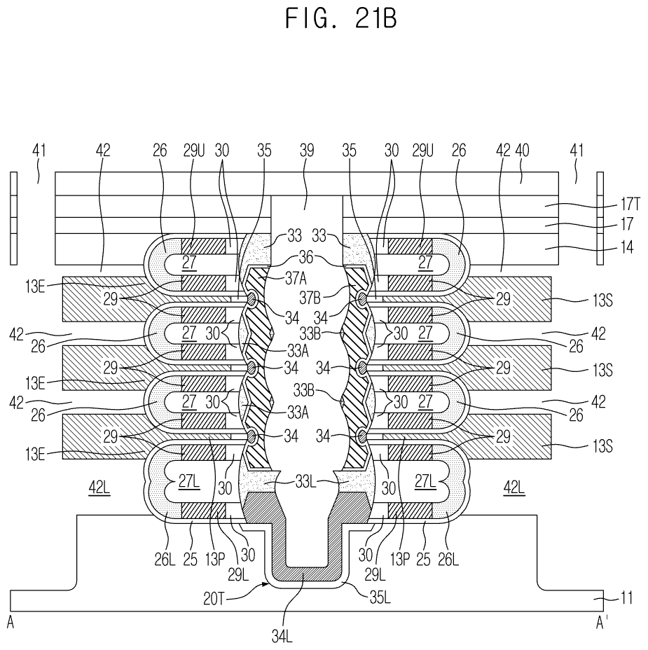

FIG. 21A is a plan view illustrating the structure at a nano sheet level for describing a method of forming second linear openings 41. FIG. 21B is a cross-sectional view of the structure taken along line A-A′ illustrated in FIG. 21A.

Referring to FIGS. 21A and 21B, an array isolation layer 39 may be formed to fill the first linear opening 20 on the first and second vertical conductive lines 37A and 37B. The array isolation layer 39 may vertically extend in the first direction D1 and horizontally extend in the third direction D3. The first and second vertical conductive lines 37A and 37B adjacent to each other in the third direction D3 may be isolated from each other by the array isolation layer 39. The array isolation layer 39 may be formed from a dielectric material such as, for example, silicon oxide, silicon nitride, an air gap, or a combination thereof.

Subsequently, the second linear openings 41 may be formed by removing the second linear sacrificial layer 19L using the fourth hard mask layer 40 as a barrier.

After the second linear openings 41 are formed, the sacrificial mold layers 12A may be selectively recessed through the second linear openings 41. To selectively recess the sacrificial mold layers 12A, a difference in etch selectivity between the sacrificial mold layers 12A and the original body portions 13A may be used. The sacrificial mold layers 12A may be removed using a wet etch or dry etch process. For example, in an embodiment the sacrificial mold layers 12A include a silicon germanium layer, the original body portions 13A include a monocrystalline silicon layer, and the silicon germanium layer may be etched by using an etchant or etch gas having a selectivity with respect to the monocrystalline silicon layer.

Subsequently, the original body portions 13A may be recessed. To recess the original body portions 13A, the wet etch or dry etch process may be used. The vertical thicknesses of the original body portions 13A may be reduced, as indicated by reference numeral “13S”. Hereinafter, the original body portions having the reduced vertical thicknesses are referred to as “recessed body portions 13S”.

Each of inter-body recesses 42 may be formed between the recessed body portions 13S. While the recessed body portions 13S and the inter-body recesses 42 are formed, the first dummy mold layer 12L and the second dummy mold layer 13L may be removed. After the first dummy mold layer 12L and the second dummy mold layer 13L are removed, the surface of the substrate 11 may be recessed. While the recessed body portions 13S and the inter-body recesses 42 are formed, a lowermost inter-body recess 42L may be formed.

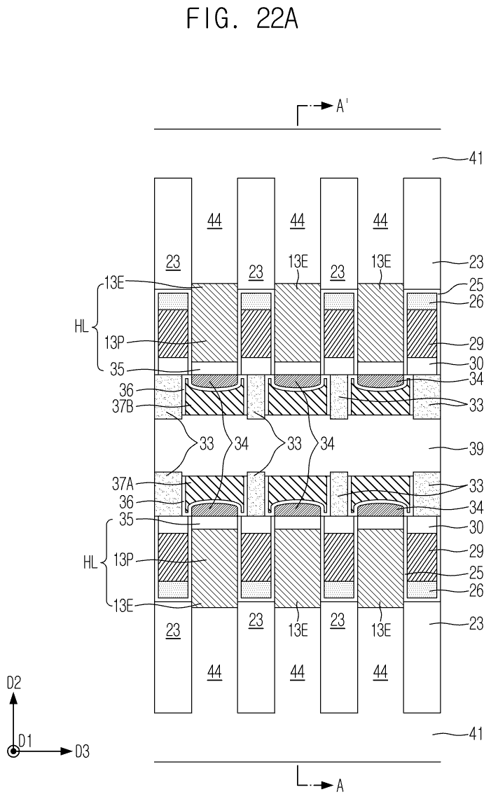

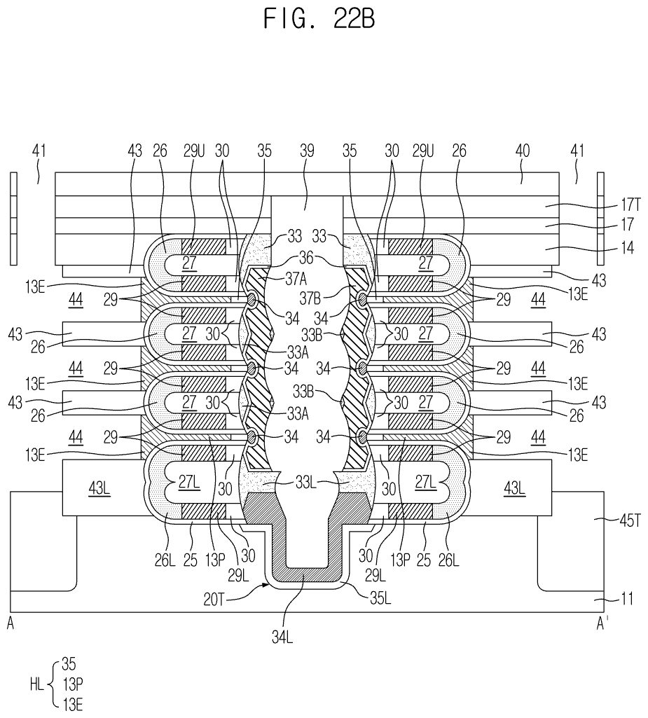

FIG. 22A is a plan view illustrating the structure at the narrow sheet level for describing a method of forming nano sheets HL. FIG. 22B is a cross-sectional view of the structure taken along line A-A′ illustrated in FIG. 22A.

Referring to FIGS. 22A and 22B, third inter-cell dielectric layers 43 may be formed by filling the inter-body recesses 42 with a dielectric material such as, for example, silicon oxide. While the third inter-cell dielectric layers 43 are formed, a lowermost third inter-cell dielectric layer 43L may also be formed to fill the lowermost inter-body recess 42L. The lowermost third inter-cell dielectric layer 43L may be a portion of the dummy structure. The third inter-cell dielectric layers 43 may correspond to the third inter-cell dielectric layers IL3 illustrated in FIGS. 4A and 4B.

After the third inter-cell dielectric layers 43 are formed, bottom protection layers 45T may be formed to fill lower portions of the second linear openings 41. The bottom protection layers 45T may each include a dielectric material. The lowermost third inter-cell dielectric layer 43L and the bottom protection layers 45T may cover the surface of the substrate 11. The bottom protection layers 45T may correspond to the bottom protection layers BTL illustrated in FIGS. 4A and 4B.

After the bottom protection layers 45T are formed, storage openings 44 may be formed by performing horizontal recessing of the recessed body portions 13S. The storage openings 44 may be referred to as “capacitor openings”. The nano sheets HL may be formed by the horizontal recessing of the recessed body portions 13S. Each of the nano sheets HL may include the narrow sheet 13P and a wide sheet 13E. The narrow sheet 13P may include the first doped region 35. The wide sheet 13E of the nano sheet HL may refer to the recessed body portion 13S remaining after the recessing. An average vertical height of the wide sheets 13E of the nano sheets HL in the first direction D1 may be greater than an average vertical height of the narrow sheets 13P. A thickness of the wide sheet 13E of the nano sheet HL may gradually increase in the second direction D2. A horizontal length of the wide sheet 13E in the second direction D2 may be less than a horizontal length of the narrow sheet 13P. The wide sheet 13E of the nano sheet HL may have a fan-like shape. The wide sheet 13E may be referred to as a “fan-shaped sheet”, and the narrow sheet 13P may be referred to as a “flat plate-shaped sheet”.

Forming the nano sheets HL (each including the wide sheet 13E) the recessed body portions 13S may be isotropically or anisotropically etched. One side of the wide sheet 13E, i.e., the side exposed by each of the storage openings 44, may have a flat shape. The one side of the wide sheet 13E may have various shapes.

Each of the nano sheets HL may include a first edge and a second edge. The first edge may refer to a portion electrically coupled to the first and second vertical conductive lines 37A and 37B, the first contact node 34 and the barrier layer 36. The second edge may refer to a portion exposed by the storage openings 44.

Each of the storage openings 44 may be disposed between the third inter-cell dielectric layers 43.

In some embodiments, the horizontal recessing of the recessed body portions 13S for forming the wide sheets 13E may stop at a boundary area between the narrow sheet 13P and the wide sheet 13E.

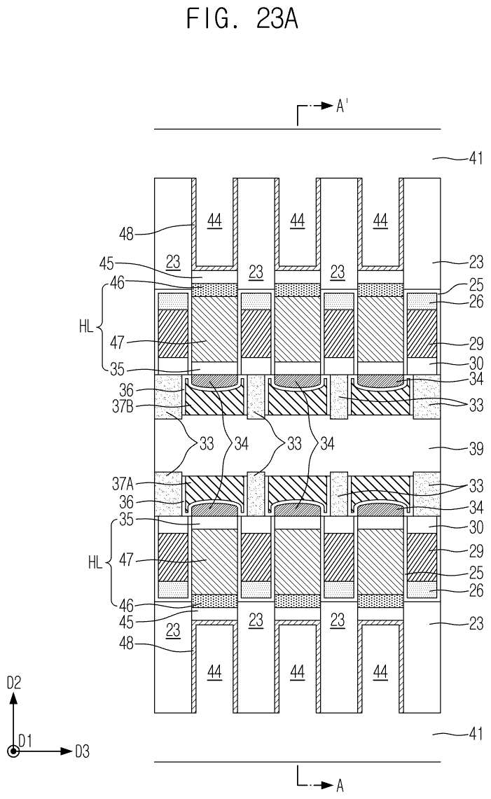

FIG. 23A is a plan view illustrating the structure at the nano sheet level for describing a method of forming second contact nodes 45 and first electrodes 48. FIG. 23B is a cross-sectional view illustrating the structure taken along line A-A′ illustrated in FIG. 23A.

Referring to FIGS. 23A and 23B, a pre-cleaning process may be performed on one side of the nano sheets HL, i.e., the surfaces of the wide sheets 13E.

Subsequently, the second contact nodes 45 may be formed on one side of the nano sheets HL, i.e., the wide sheets 13E. Forming the second contact nodes 45 may include selective epitaxial growth (SEG). For example, a semiconductive material may be grown from the side surfaces of the wide sheets 13E through the SEG. The second contact nodes 45 may each include SEG Si. Because the wide sheets 13E each include monocrystalline silicon, a silicon layer may be epitaxially grown along crystal surfaces of the side surfaces of the wide sheets 13E.

The second contact nodes 45 may each include a dopant. When the silicon layer is grown using the SEG, the dopants may be doped in situ. Accordingly, the second contact nodes 45 may each be a doped epitaxial layer. The second contact nodes 45 may each include an N-type dopant as the dopant including, for example, phosphorus, arsenic, antimony, or a combination thereof. The second contact nodes 45 may each include a phosphorus-doped silicon epitaxial layer formed by the SEG, i.e., doped SEG SiP. In some embodiments, the first contact nodes 34 may also be formed through the SEG.

Because the second contact nodes 45 are formed using the SEG, void-free or seam-free second contact nodes 45 may be formed. Because the second contact nodes 45 are formed using the SEG, a process for forming the second contact nodes 45 may be simplified.

Each of the second contact nodes 45 may be disposed between the third inter-cell dielectric layers 43 that are vertically stacked.

The second doped regions 46 may be formed in the wide sheets 13E of the nano sheets HL. A heat treatment process may be performed to form the second doped regions 46, so that the dopants may be diffused from the second contact nodes 45 to the doped regions.

Each of the nano sheets HL may include the first doped region 35, the second doped region 46, and a channel 47. The channel 47 may be defined between the first doped region 35 and the second doped region 46. The first doped region 35 and the channel 47 may be formed in the narrow sheet 13P. The second doped region 46 may be formed in the wide sheet 13E. A portion of the second doped region 46 may extend into the narrow sheet 13P. One side of each of the second doped regions 46 of the nano sheets HL may be coupled to the channel 47. The other side of each of the second doped regions 46 of the nano sheets HL may be coupled to the second contact nodes 45.

In some embodiments, an ohmic contact layer including metal silicide may be further formed after the second contact nodes 45 are formed.

The second contact nodes 45 may correspond to the second contact nodes SNC illustrated in FIGS. 4A and 4B. The second doped regions 46 may correspond to the second doped regions DR illustrated in FIGS. 4A and 4B.

Subsequently, the first electrodes 48 of a data storage element may be formed on the second contact nodes 45. The first electrodes 48 may each have a horizontally-oriented cylindrical shape. Each of the first electrodes 48 may be disposed in a different one of the storage openings 44. The first electrodes 48 adjacent to each other in the second direction D2 may be spaced apart from each other by the second linear openings 41. The first electrodes 48 adjacent to each other in the third direction D3 may be spaced apart from each other by the first inter-cell dielectric layers 23. The first electrodes 48 adjacent to each other in the first direction D1 may be spaced apart from each other by the third inter-cell dielectric layers 43. Forming the first electrodes 48 may include depositing a metal material, gap-filling a sacrificial material, and isolating the metal material in a vertical/horizontal direction. The sacrificial material may include oxide or polysilicon.

Each of the first electrodes 48 may include an inner space and a plurality of outer surfaces. The inner space of the first electrode 48 may include a plurality of inner surfaces. The outer surfaces of the first electrode 48 may include a vertical outer surface and a plurality of horizontal outer surfaces. The vertical outer surface of the first electrode 48 may vertically extend in the first direction D1. The horizontal outer surfaces of the first electrode 48 may horizontally extend in the second direction D2 or the third direction D3. The inner space of the first electrode 48 may be a three-dimensional space. The first electrode 48 may have a cylindrical shape.

The first electrode 48 may include metal, noble metal, metal nitride, conductive metal oxide, conductive noble metal oxide, metal carbide, metal silicide, or a combination thereof. For example, the first electrode 48 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof.

The first electrodes 48 may correspond to the first electrodes SN illustrated in FIGS. 4A and 4B.

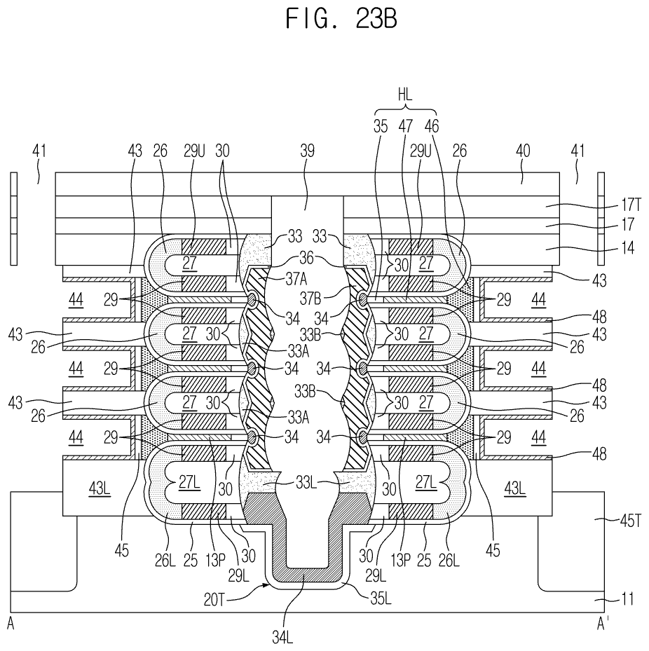

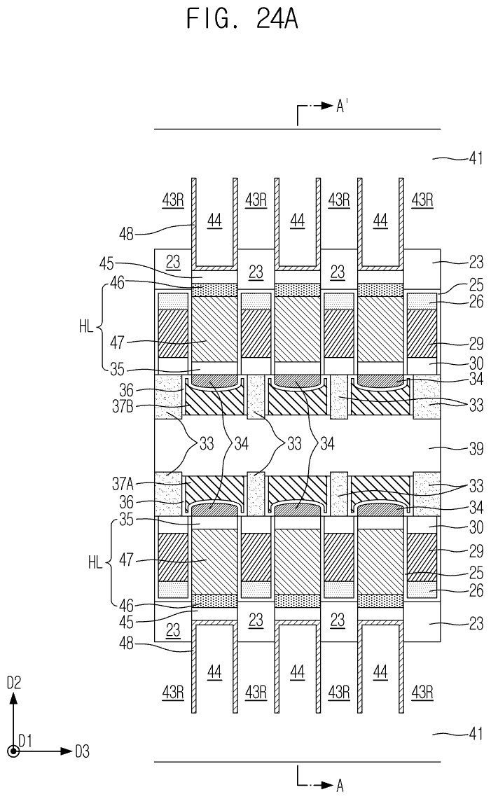

FIG. 24A is a plan view illustrating the structure at the nano sheet level for describing a method for recessing the first and third inter-cell dielectric layers 23 and 43. FIG. 24B is a cross-sectional view of the structure taken along line A-A′ illustrated in FIG. 24A.

Referring to FIGS. 24A and 24B, portions of the first and third inter-cell dielectric layers 23 and 43 may be horizontally recessed as indicated by reference numeral “43R”. Accordingly, outer walls of the first electrodes 48 may be partially exposed. The first electrodes 48 may each have a semi-cylindrical shape. Horizontal recess depths of the first and third inter-cell dielectric layers 23 and 43 may be depths that do not expose the second contact nodes 45. The semi-cylindrical shape of each of the first electrodes 48 may include cylindrical inner surfaces and semi-cylindrical outer surfaces.

FIG. 25A is a plan view illustrating the structure at the nano sheet level for describing a method of forming a second electrode 50. FIG. 25B is a cross-sectional view of the structure taken along line A-A′ illustrated in FIG. 25A.

Referring to FIGS. 25A and 25B, a dielectric layer 49 and the second electrode 50 may be sequentially formed on the first electrodes 48. The first electrode 48, the dielectric layer 49 and the second electrode 50 may be a data storage element CAP. The second electrodes 50 of the data storage elements CAP may be merged with one another and form a common plate PL. The dielectric layer 49 and the second electrode 50 may correspond to the dielectric layer DE and the second electrode PN illustrated in FIGS. 4A and 4B.

The dielectric layer 49 and the second electrode 50 may be disposed on the cylindrical inner surfaces of the first electrode 48. A portion of the dielectric layer 49 and a portion of the second electrode 50 may extend to be disposed on the semi-cylindrical outer surfaces of the first electrode 48.

The dielectric layer 49 may be referred to as a “capacitor dielectric layer” or a “memory layer”. The dielectric layer 49 may include silicon oxide, silicon nitride, a high-k material, a ferroelectric material, an antiferroelectric material, a perovskite material, or a combination thereof. The dielectric layer 49 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 49 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, an HA (HfO₂/Al₂O₃) stack, an HAH (HfO₂/Al₂O₃/HfO₂) stack, an HAHA (HfO₂/Al₂O₃/HfO₂/Al₂O₃) stack, an HAHAH (HfO₂/Al₂O₃/HfO₂/Al₂O₃/HfO₂) stack, an HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, an HZHZ (HfO₂/ZrO₂/HfO₂/ZrO₂) stack, or an AHZAZHA (Al₂O₃/HfO₂/ZrO₂/Al₂O₃/ZrO₂/HfO₂/Al₂O₃) stack.

The second electrode 50 may include metal, noble metal, metal nitride, conductive metal oxide, conductive noble metal oxide, metal carbide, metal silicide, or a combination thereof. For example, the second electrode 50 may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TiN/W) stack, or a combination thereof. The second electrode 50 may also include a combination of a metal-based material and a silicon-based material. For example, a titanium nitride, tungsten and polysilicon may be sequentially stacked in the second electrode 50.

In some embodiments, a plurality of interface control layers may be further included between the first electrode 48 and the dielectric layer 49 and between and the dielectric layer 49 and the second electrode 50 to alleviate leakage current. Each of the interface control layers may include titanium oxide (TiO₂), tantalum oxide (Ta₂O₅), niobium oxide (Nb₂O₅), niobium nitride (NbN), niobium oxynitride (NbON), or a combination thereof. The data storage element CAP may include a first interface control layer, a second interface control layer, or a combination thereof. The first interface control layer and the second interface control layer may be conductive or dielectric. The first interface control layer may be formed between the first electrode 48 and the dielectric layer 49, and the second interface control layer may be formed between the dielectric layer 49 and the second electrode 50. The first interface control layer and the second interface control layer may be made of the same material or different materials. For example, a structure in which the first interface control layer, dielectric layer 49 and second interface control layer of the data storage element CAP are sequentially stacked may include an NZHZAZHZATN (Nb₂O₅/ZrO₂/HfO₂/ZrO₂/Al₂O₃/ZrO₂/HfO₂/ZrO₂/Al₂O₃/TiO₂/Nb₂O₅) stack.

As described above, the method for fabricating the semiconductor device may include forming the nano sheet target layers 13 that are spaced apart from each other and are vertically stacked over the substrate 11, forming the flat plate-shaped narrow sheets 13P that trim the first portions of the nano sheet target layers 13, horizontally recessing the second portions of the nano sheet target layers 13 and forming the fan-shaped wide sheets 13E, selectively growing the second contact nodes 45 on the side surfaces of the wide sheets 13E, and forming the data storage elements CAP each coupled to a different one of the second contact nodes 45.

From another perspective, the method for fabricating the semiconductor device may include forming the nano sheet target layers 13 that are spaced apart from each other and are vertically stacked over the substrate 11, forming the flat plate-shaped narrow sheets 13P that trim the first portions of the nano sheet target layers 13, forming the horizontal conductive lines 29 that extend while surrounding the narrow sheets 13P disposed at the same horizontal level, forming the first contact nodes 34 each coupled to a different one of the narrow sheets 13P, forming the first and second vertical conductive lines 37A and 37B coupled to the first contact nodes 34, horizontally recessing the second portions of the nano sheet target layers 13P and forming the fan-shaped wide sheets 13E, selectively growing the second contact nodes 45 on side surfaces of the wide sheets 13E, and forming the data storage elements CAP each coupled to a different one of the second contact nodes 45.

In some embodiments, the recessing of the first and third inter-cell dielectric layers 23 and 43 illustrated in FIG. 24B may be omitted. Thereafter, as illustrated in FIG. 25B, the dielectric layer 49 and the second electrode 50 may be formed. Accordingly, the data storage element CAP including the first electrode 48 having a concave shape may be formed.

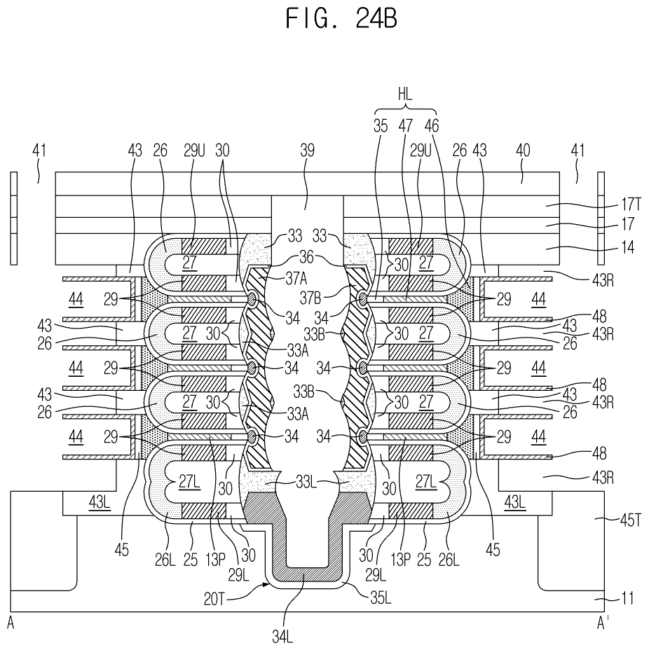

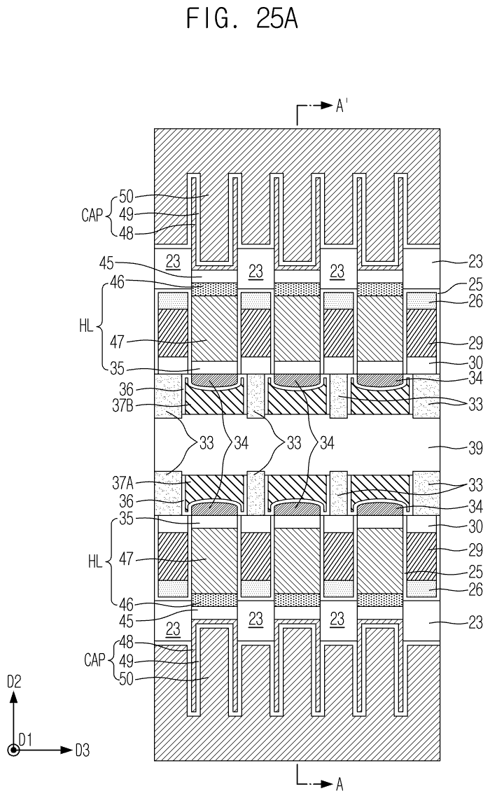

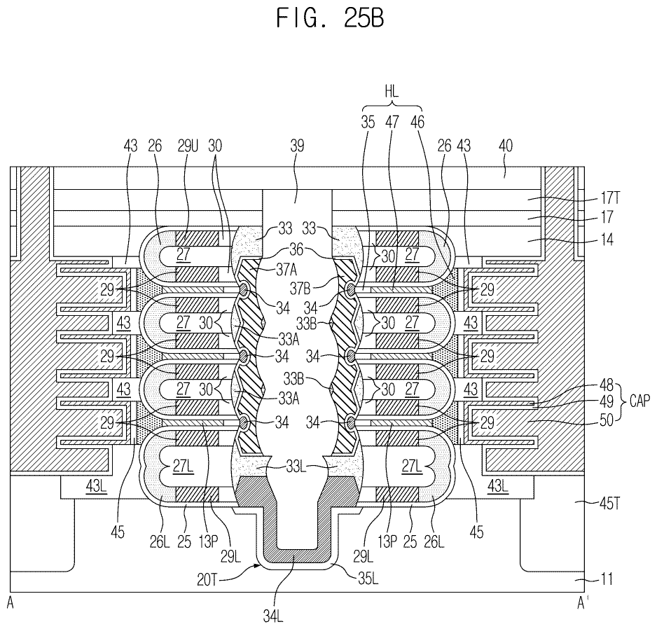

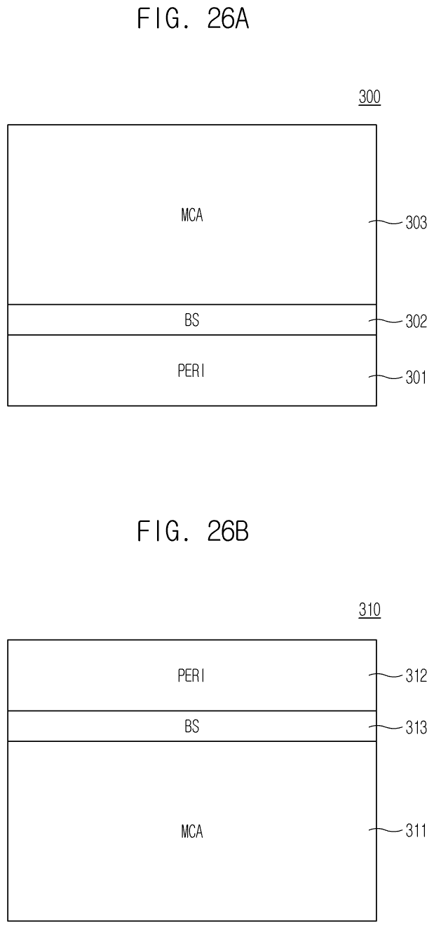

FIGS. 26A and 26B are schematic cross-sectional views of semiconductor devices 300 and 310 in accordance with embodiments of the present disclosure.

Referring to FIG. 26A, the semiconductor device 300 may include a peripheral circuit portion (PERI) 301, a memory cell array (MCA) 303, and a bonding interface (BS) 302. The bonding interface 302 may be disposed between the memory cell array 303 and the peripheral circuit portion 301. In the semiconductor device 300, the memory cell array 303 may be disposed at a level higher than the peripheral circuit portion 301. The semiconductor device 300 may be referred to as a “Peri Under Cell array (PUC) structure”. The memory cell array 303 may include a substrate on which back-grinding is performed and an array of memory cells. For example, as described with reference to FIG. 25B, after the data storage element CAP is formed, the substrate 11 may be flipped over through wafer-flipping, and then a back side of the substrate 11 may be partially ground.

Referring to FIG. 26B, the semiconductor device 310 may include a memory cell array (MCA) 311, a peripheral circuit portion (PERI) 312, and a bonding interface (BS) 313. The bonding interface 313 may be disposed between the memory cell array 311 and the peripheral circuit portion 312. In the semiconductor device 310, the memory cell array 311 may be disposed at a level lower than the peripheral circuit portion 312. The semiconductor device 310 may be referred to as a “Cell array Under Peri (CUP) structure”. Forming the peripheral circuit portion 312 may include forming a plurality of control circuits on a peripheral circuit substrate and forming multi-level interconnection on the control circuits.

In FIG. 26A and FIG. 26B, the bonding interfaces 302 and 313 may each include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for the memory cell arrays 303 and 311, forming a peripheral circuit bonding pad for the peripheral circuit portions 301 and 312, performing the wafer-flipping so that the cell bonding pad and the peripheral circuit bonding pad face each other, and performing wafer bonding.

The semiconductor device 300 illustrated in FIG. 26A may perform the wafer-flipping on the substrate on which the memory cell array is formed so that the cell bonding pad and the peripheral circuit bonding pad face each other, after the cell bonding pad and the peripheral circuit bonding pad are formed. The semiconductor device 310 illustrated in FIG. 26B may perform the wafer-flipping on the substrate on which the peripheral circuit portion is formed so that the cell bonding pad and the peripheral circuit bonding pad face each other, after the cell bonding pad and the peripheral circuit bonding pad are formed.

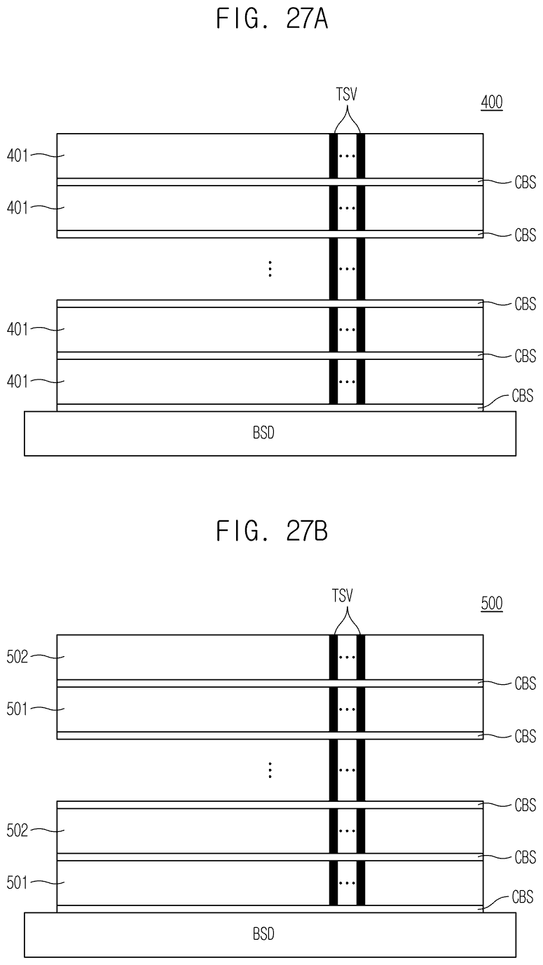

FIGS. 27A and 27B illustrate various views illustrating stack assemblies 400 and 500 in accordance with embodiments of the present disclosure.

Referring to FIG. 27A, the stack assembly 400 may include an assembly of semiconductor dies. For example, the stack assembly 400 may include a first semiconductor die BSD and a plurality of second semiconductor dies 401. The first semiconductor die BSD may include logic circuits. Each of the second semiconductor dies 401 may include memory cell arrays according to embodiments described above. Each of the second semiconductor dies 401 may include structures in which a memory cell array and a peripheral circuit portion are stacked, for example, the semiconductor device 300 illustrated in FIG. 26A or the semiconductor device 310 illustrated in FIG. 26B. The logic circuits of the first semiconductor die BSD may be different from the peripheral circuit portions of the second semiconductor dies 401. The second semiconductor dies 401 may be at a chip level or a wafer level.

The second semiconductor dies 401 may be electrically coupled to each other through a plurality of through silicon vias TSV and bonding interfaces CBS. The first semiconductor die BSD and a lowermost second semiconductor die 401 may be electrically coupled to each other through the bonding interface CBS. The second semiconductor dies 401 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In some embodiments, to form the bonding interface CBS, the second semiconductor dies 401 may be flipped over through wafer-flipping, and back sides of the second semiconductor dies 401 may be ground.

Referring to FIG. 27B, the stack assembly 500 may include an assembly of semiconductor dies. For example, the stack assembly 500 may include a first semiconductor die BSD, a plurality of second semiconductor dies 501, and a plurality of third semiconductor dies 502. The first semiconductor die BSD may include logic circuits. Each of the second semiconductor dies 501 and each of the third semiconductor dies 502 may include memory cell arrays according to embodiments described above. The second semiconductor dies 501 and the third semiconductor dies 502 may have different structures.

Each of the second semiconductor dies 501 may include the semiconductor device 300 illustrated in FIG. 26A in which a memory cell array is stacked over a peripheral circuit portion. Each of the third semiconductor dies 502 may include the semiconductor device 310 illustrated in FIG. 26B in which a peripheral circuit portion is stacked over a memory cell array.

In some embodiments, each of the second semiconductor dies 501 may include the semiconductor device 310 illustrated in FIG. 26B in which a peripheral circuit portion is stacked over a memory cell array, and each of the third semiconductor dies 502 may include the semiconductor device 300 illustrated in FIG. 26A in which a memory cell array is stacked over a peripheral circuit portion.

The logic circuits of the first semiconductor die BSD may be different from the peripheral circuit portions of the second and third semiconductor dies 501 and 502. The second and third semiconductor dies 501 and 502 may be at a chip level or a wafer level.

The second and third semiconductor dies 501 and 502 may be electrically coupled to each other through a plurality of through silicon vias TSV and bonding interfaces CBS. The first semiconductor die BSD and a lowermost second semiconductor die 501 may be electrically coupled to each other through the bonding interface CBS. The second and third semiconductor dies 501 and 502 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

The stack assemblies 400 and 500 described with reference to FIGS. 27A and 27B may be high bandwidth memories.

According to various embodiments of the present disclosure, it is possible to prevent bridging between bottom portions of vertical conductive lines because the vertical conductive lines are formed to be self-aligned with a supporter structure and a bottom isolation portion.

According to various embodiments of the present disclosure, it is possible to reduce the fabrication cost of a semiconductor device and simplify the fabrication process of the semiconductor device because vertical conductive lines having a silicon on insulator-free (SOI-free) structure are formed.

While the embodiments of the present disclosure have been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A semiconductor device comprising:
vertical and horizontal arrangements of nano sheets that are horizontally oriented;
a vertical arrangement of first conductive lines that surround portions of the nano sheets in the horizontal arrangement;
a supporter structure adjacent to the vertical and horizontal arrangements of the nano sheets;
second conductive lines embedded in the supporter structure and coupled in common to first edges of the nano sheets in the vertical arrangement; and
a dummy structure including a bottom isolation portion in contact with bottom portions of the second conductive lines.

2. The semiconductor device of claim 1, wherein the supporter structure includes a plurality of support openings that expose the first edges of the nano sheets in common, and the second conductive lines are disposed in the support openings.

3. The semiconductor device of claim 1, wherein the supporter structure has an integral structure made of a dielectric material.

4. The semiconductor device of claim 1, wherein the supporter structure includes a low-k material, silicon carbon oxide, silicon nitride, an air gap, or a combination thereof.

5. The semiconductor device of claim 1, wherein the supporter structure includes:
support bodies that are vertically oriented;
support openings between the support bodies;
inner spacers configured to couple the support bodies to each other and are disposed adjacent to the nano sheets; and
outer spacers disposed adjacent to the second conductive lines,
wherein the second conductive lines are disposed in the support openings of the supporter structure.

6. The semiconductor device of claim 1, wherein the bottom isolation portion and the supporter structure have an integral structure.

7. The semiconductor device of claim 1, wherein the bottom isolation portion contacts the bottom portions of the second conductive lines and extends horizontally.

8. The semiconductor device of claim 1, wherein the second conductive lines include non-linear sidewalls which contact the supporter structure.

9. The semiconductor device of claim 6, wherein non-linear sidewalls of the second conductive lines include a plurality of angled corners.

10. The semiconductor device of claim 1, wherein each of the nano sheets includes a first doped region, a channel, and a second doped region, which are horizontally arranged, and
wherein the first conductive lines surround the channels of the nano sheets in the horizontal arrangement and extend horizontally.

11. The semiconductor device of claim 1, further comprising:
first contact nodes formed on the first edges of the nano sheets; and
second contact nodes formed on second edges of the nano sheets.

12. The semiconductor device of claim 11, wherein the first contact nodes and the second contact nodes each include a selective epitaxial growth layer.

13. The semiconductor device of claim 1, wherein the dummy structure further includes:
a dummy dielectric layer horizontally disposed from the bottom isolation portion;
a dummy spacer that covers one side of the dummy dielectric layer; and
a dummy conductive line disposed between the dummy dielectric layer and a lower structure.

14. The semiconductor device of claim 1, further comprising data storage elements coupled to second edges of the nano sheets.
